(19) United States
(12) Patent Application Publication
(10) Pub. No.: US 2026/0215000 A1
(43) Pub. Date: Jul. 23, 2026

(54) SEMICONDUCTOR DEVICE AND METHODS OF FORMATION

(71) Applicant: Taiwan Semiconductor Manufacturing Company, Ltd., Hsinchu (TW)

(72) Inventors: Lin-Yu HUANG, Hsinchu (TW); Shih-Fan CHEN, Hsinchu City (TW); Sheng-Fu HSU, Hsinchu (TW)

(21) Appl. No.: 19/033,714

(22) Filed: Jan. 22, 2025

(51) Int. Cl. H10D 89/60

(52) U.S. Cl. CPC H10D 89/814

(57) ABSTRACT

A semiconductor device includes an electrostatic discharge (ESD) protection device that includes a plurality of non-contiguous implant portions that are spaced apart with respective well regions between the non-contiguous implant portions in a substrate of the semiconductor device. The space between the non-contiguous implant portions provides areas in the substrate in which dopants from the non-contiguous implant portions may diffuse. Thus, the dopants can diffuse into the substrate across a greater area of the substrate than in a source/drain region including continuous implant portions. As a result, the dopant concentration from the implant portions may be reduced in the substrate. This reduces the build-up and concentration of dopants near a gate structure, which reduces the strength of the electric field near the gate structure. The reduced strength of the electric field near the gate structure lessens the damage caused to the ESD protection device across multiple ESD events.

### BACKGROUND

Electrostatic discharge (ESD) is a concern for semiconductor integrated circuits (ICs). If not handled properly, an ESD event can result in a high voltage that may damage device circuitry of a semiconductor device. To prevent ESD-related damage, a semiconductor device may include an ESD protection circuit. The ESD protection circuit may be operable to divert electrical current away from device circuitry of the semiconductor device during an ESD event, thereby protecting the device circuitry from being damaged by the ESD event.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1A and B are diagrams of an example semiconductor device described herein.

FIGS. 2A-2C are diagrams of example implementations of gate structures included in an electrostatic discharge (ESD) protection device described herein.

FIGS. 3A-3I are diagrams of an example implementation of ESD protection structures of a semiconductor device described herein.

FIGS. 4A-4K are diagrams of an example implementation of forming an interconnect layer of a semiconductor device described herein.

FIGS. 5A and 5B are diagrams of an example semiconductor device described herein.

FIGS. 6A-6J are diagrams of an example implementation of ESD protection structures of a semiconductor device described herein.

FIGS. 7A-7L are diagrams of an example implementation of forming an interconnect layer of a semiconductor device described herein.

FIGS. 8A-8D are diagrams of example semiconductor devices described herein.

FIGS. 9A-9D are diagrams of example semiconductor devices described herein.

FIG. 10 is a diagram of an example semiconductor device described herein.

FIG. 11 is a flowchart of an example process associated with forming an ESD protection device described herein.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

An electrostatic discharge (ESD) protection device may be included between regions of a semiconductor device to provide ESD protection for ESD events that might otherwise propagate between the regions of the semiconductor device. For example, an ESD protection device may be included between an input/output (I/O) region and a core integrated circuit (IC) region to protect the core IC region from ESD events that enter the semiconductor device through the I/O region.

The ESD protection device may include one or more gate-drain voltage (VDD) and/or grounded-gate metal-oxide-semiconductor field effect transistors (MOSFETs) such as a gate-VDD p-type MOSFET (e.g., gdPMOS) device and/or a grounded-gate n-type MOSFET (ggNMOS) device. Gate-VDD and grounded-gate ESD protection devices have advantages including low trigger voltage, low power dissipation, and full compatibility with BCD (bipolar/complementary-metal-oxide-semiconductor (CMOS)/double diffused metal-oxide-semiconductor (DMOS)) technology. As indicated by the names, the gate structure of a gate-VDD MOSFET is electrically connected to a drain voltage, and the gate structure of a grounded-gate MOSFET is electrically grounded. A source/drain region of the grounded-gate MOSFET is electrically connected to the I/O region. When an ESD event such as a voltage spike occurs, a high voltage is applied to the source/drain region, which causes a low impedance path to be formed between the source/drain region and electrical ground. Thus, the grounded-gate MOSFET effectively clamps the voltage at the source/drain region to a safe level, thereby protecting the core IC region from being damaged by the voltage spike.

An ESD protection device may be designed and manufactured to satisfy one or more ESD protection requirements or standards according to an ESD model, such as the human body model (HBM). Here, the ESD protection device needs to survive and provide ESD protection at particular voltage levels for particular durations of time in order to be certified as satisfying the one or more ESD protection requirements or standards.

In some cases, repeated exposure to ESD events can cause an ESD protection device to become damaged, resulting in low performance and/or failure of the ESD protection device. For example, dopant concentration in a substrate of the ESD protection device near the gate structure of a grounded-gate MOSFET may result in an electrical field in the substrate being concentrated at an interface between a p-doped region and an n-doped region in the substrate near the gate structure. The strength of the electric field at the interface, resulting from the concentration of p-type and n-type dopants, may accelerate the damage caused to the ESD protection device, thereby leading to accelerated burnout and failure of the ESD protection device.

In some implementations described herein, a semiconductor device includes an ESD protection device that includes a plurality of non-contiguous implant portions that are spaced apart with respective well regions between the non-contiguous implant portions in a substrate of the semiconductor device. The space between the non-contiguous implant portions provides areas in the substrate in which dopants from the non-contiguous implant portions may diffuse. Thus, the dopants, which may have been added during, for example, manufacturing operations for the semiconductor device, diffuse into the substrate across a greater area of the substrate than in a source/drain region including continuous implant portions. As a result, the dopant concentration from the implant portions may be reduced in the substrate. This reduces the build-up and concentration of dopants near a gate structure, which reduces the strength of the electric field near the gate structure. The reduced strength of the electric field near the gate structure lessens the damage caused to the ESD protection device across multiple ESD events, thereby increasing the operational life of the ESD protection device.

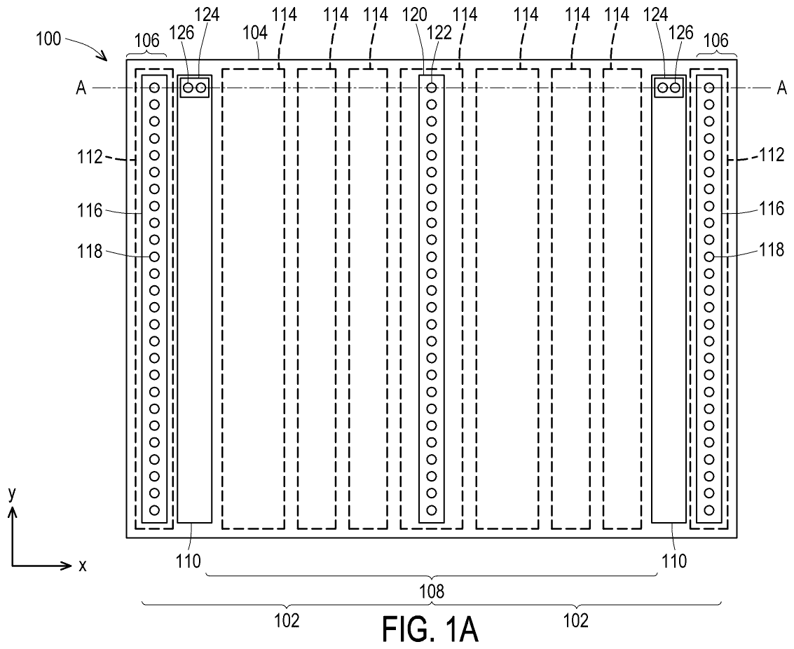

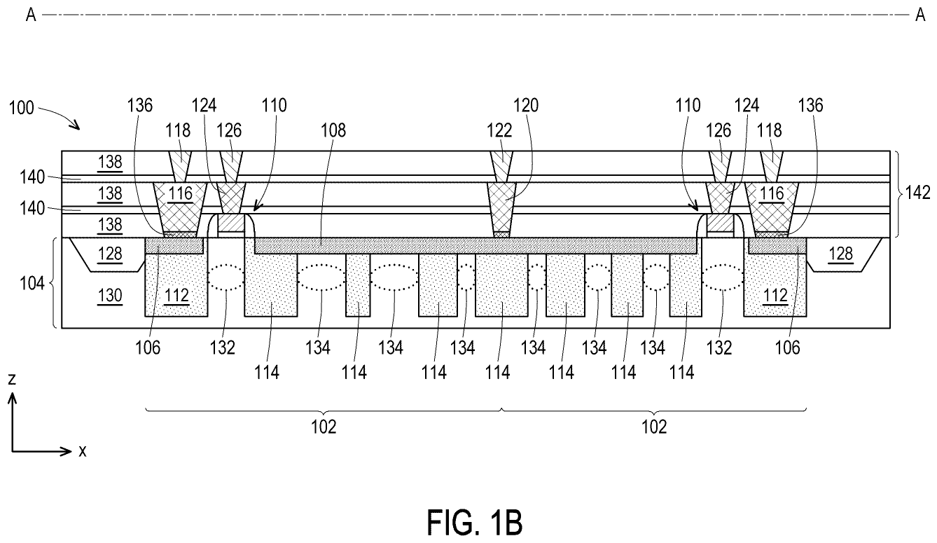

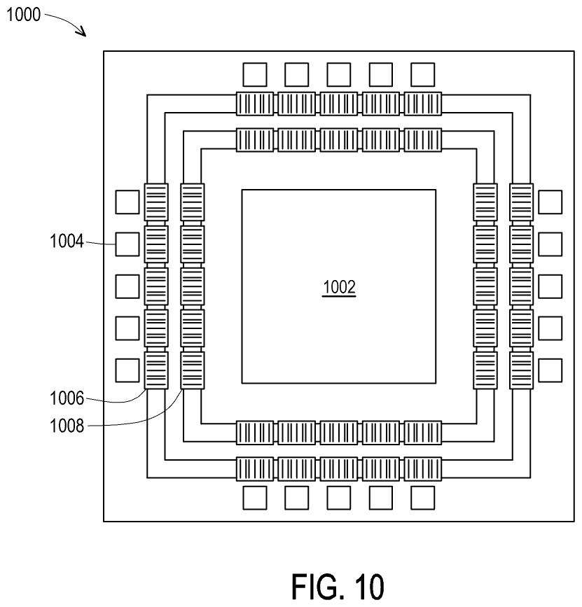

FIGS. 1A and 1B are diagrams of an example semiconductor device 100 described herein. FIG. 1A illustrates a top view of the semiconductor device 100. As shown in FIG. 1A, the semiconductor device 100 includes one or more ESD protection devices 102. One or more of the semiconductor devices 100 may be included in another semiconductor device, such as a semiconductor device 1000 of FIG. 10, to provide ESD protection for integrated circuit devices of the other semiconductor device.

As shown in FIG. 1A, the semiconductor device 100 includes a substrate 104 on which the one or more ESD protection devices 102 may be formed. The substrate 104 may include a silicon (Si) substrate, a substrate formed of a material including silicon, a III-V compound semiconductor material substrate such as gallium arsenide (GaAs), a silicon on insulator (SOI) substrate, a germanium (Ge) substrate, a silicon germanium (SiGe) substrate, a silicon carbide (SiC) substrate, or another type of semiconductor substrate. The substrate 104 may include various layers, including conductive or insulating layers formed on a semiconductor substrate. The substrate 104 may include a compound semiconductor and/or an alloy semiconductor. The substrate 104 may include various doping configurations to satisfy one or more design parameters. For example, different doping profiles (e.g., n-wells, p-wells) may be formed on the substrate 104 in regions designed for different device types (e.g., p-type metal-oxide-semiconductor (PMOS) nanostructure transistors, n-type metal-oxide-semiconductor (NMOS) nanostructure transistors). The suitable doping may include ion implantation of dopants and/or diffusion processes. Further, the substrate 104 may include an epitaxial layer (epi-layer), may be strained for performance enhancement, and/or may have other suitable enhancement features. The substrate 104 may include a portion of a semiconductor wafer on which other semiconductor devices are formed.

As further shown in FIG. 1A, an ESD protection device 102 includes a source/drain region 106 and a source/drain region 108 in the substrate 104, and a gate structure 110 between the source/drain regions 106 and 108. The source/drain region 106, the source/drain region 108, and the gate structure 110 are arranged in an x-direction in the semiconductor device 100 and may extend approximately parallel to each other in the y-direction in the semiconductor device 100. The source/drain region 106 may be located adjacent to a first side of gate structure 110, and the source/drain region 108 may be located adjacent to a second side of the gate structure 110 opposing the first side.

An ESD protection device 102 may correspond to a grounded-gate MOSFET, a gate-VDD MOSFET, or another type of ESD protection transistor structure. The gate structure 110 may correspond to the gate of a grounded-gate MOSFET or the gate of a gate-VDD MOSFET, and the source/drain regions 106 and 108 may correspond to the source/drain regions of the grounded-gate MOSFET or the gate of a gate-VDD MOSFET. A gate structure 110 is operational and may be connected to back end circuitry in the semiconductor device 100. “Source/drain region” may refer to a source or a drain, individually or collectively, depending upon the context. In some implementations, the source/drain region 106 is a source region of the grounded-gate MOSFET or of the gate-VDD MOSFET, and the source/drain region 108 is a drain region of the grounded-gate MOSFET or of the gate-VDD MOSFET. The grounded-gate MOSFET or the gate-VDD MOSFET may be a planar transistor, a fin field effect transistor (finFET), a nanostructure (e.g., a gate all around (GAA) transistor, a nanowire transistor, a nanosheet transistor, a multi-bridge channel transistor, a nanoribbon transistor), and/or another type of transistor structure. In some implementations, the source/drain region 108 may be electrically connected to an I/O integrated circuit device of another semiconductor device in which the semiconductor device 100 is included.

As further shown in FIG. 1A, an ESD protection device 102 may include a plurality of implant regions, such as a lightly doped implant region 112 and a plurality of lightly doped implant regions 114. As explained in more detail in connection with FIG. 1B. the lightly doped implant regions 112 and 114 may be formed in a well region, and may each include the same dopant type, such as an n-type dopant or a p-type dopant. Examples of n-type dopants include phosphorous (P), arsenic (As), bismuth (Bi), and/or stibium (Sb), among other examples. Examples of p-type dopants include boron (B), aluminum (Al), gallium (Ga), and/or antimony (Sb). The dopant type of the lightly doped implant regions 112 and 114 may be different from the dopant type of the well region.

As further shown in FIG. 1A, a source/drain contact 116 is included on and electrically connected with the source/drain region 106, and one or more source/drain interconnects 118 are included on and electrically connected with the source/drain contact 116. Similarly, a source/drain contact 120 is included on and electrically connected with the source/drain region 108, and one or more source/drain interconnects 122 are included on and electrically connected with the source/drain contact 120. In some implementations, the source/drain contacts 116 and 120 are each elongated conductive structures that extend in the y-direction. The source/drain interconnects 118 may be arranged in the y-direction along the source/drain contact 116, and the source/drain interconnects 122 may be arranged in the y-direction along the source/drain contact 120. A gate contact 124 may be included on an end of the gate structure 110, and one or more gate interconnects 126 may be included on and electrically connected with the gate contact 124.

FIG. 1B illustrates a cross-section view of the semiconductor device 100 along the line A-A in FIG. 1A. As shown in FIG. 1B, the semiconductor device 100 may include a plurality of shallow trench isolation (STI) regions 128 in the substrate 104 at opposing ends of the ESD protection devices 102. The STI regions 128 may include a dielectric material such as a silicon oxide (SiOₓ), a silicon nitride (SiₓN_{y}), a silicon oxynitride (SiON), fluoride-doped silicate glass (FSG), a low dielectric constant (low-k) dielectric material, and/or another suitable insulating material. The STI regions 128 may include a multi-layer structure, for example, having one or more liner layers.

As further shown in FIG. 1B, an ESD protection device 102 may include a plurality of doped regions that are included in the substrate 104. For example, an ESD protection device 102 may include a well region 130 in the substrate 104. The well region 130 may include a first dopant type. For example, the well region 130 may include a p-doped well that includes one or more p-type dopants, such as boron (B), gallium (Ga), and/or indium (In), among other examples.

As another example, an ESD protection device 102 may include a plurality of implant regions in the well region 130, such as the lightly doped implant region 112 and a plurality of the lightly doped implant regions 114. The lightly doped implant regions 112 and 114 may each include the same dopant type, such as an n-type dopant. The dopant type of the lightly doped implant regions 112 and 114 may be different from the dopant type of the well region 130.

The plurality of lightly doped implant regions 114 include a plurality of non-contiguous (e.g., discontinuous) implant regions that are spaced apart from each other along the x-direction (e.g. a direction along a top surface of the substrate 104) with respective portions of the well region 130 in the spaces between the non-contiguous implant regions. The spaces between adjacent lightly doped implant regions 114 provides areas in the substrate 104 in which dopants from the non-contiguous lightly doped implant regions 114 may diffuse. Thus, the dopants, which may have been added during, for example, manufacturing operations for the semiconductor device 100, diffuse into the substrate 104 across a greater area of the substrate 104 than if the lightly doped implant regions 114 under the source/drain region 108 were a single continuous implant region. As a result, the dopant concentration from the lightly doped implant regions 114 is reduced in the substrate 104. This reduces the build-up and concentration of dopants near gate structures 110, which reduces the strength of the electric field near the gate structures 110. The reduced strength of the electric field near the gate structures lessens the damage caused to the ESD protection devices 102 across multiple ESD events, thereby increasing the operational life of the ESD protection devices 102.

The source/drain region 108 includes a continuous implant segment that extends in the x-direction through top portions of the plurality of non-contiguous lightly doped implant regions 114 and through top portions of the well region 130 in the spaces between the adjacent lightly doped implant regions 114. The continuous implant segment extends between an edge of a first gate structure 110 and an edge of a second gate structure 110. In some implementations, the two gate structures 110 respectively correspond to two ESD protection devices 102 and share the source/drain region 108. Alternatively, the two gate structures 110 correspond to the same ESD protection device 102 and share the source/drain region 108. The source/drain regions 106 each include implant segments disposed at top portions of the lightly doped implant regions 112.

The implant segments of the source/drain region 106 and of the source/drain region 108 may include the same dopant type, which may be the same dopant type as the lightly doped implant regions 112 and 114. For example, the source/drain region 106 and the source/drain region 108 may each include n-type dopants such as phosphorous (P), arsenic (As), bismuth (Bi), and/or stibium (Sb), among other examples. However, the dopant concentration in the source/drain region 106 and in the source/drain region 108 may be greater than the dopant concentration in the lightly doped implant regions 112 and 114. The lightly doped implant region 112 may be referred to as a lightly doped drain (LDD) region of the source/drain region 106, and the lightly doped implant region 114 may be referred to as an LDD region of the source/drain region 108. “Dopant concentration” may refer to a concentration of dopant for a specific volume corresponding to a well region 130, lightly doped implant region 112 or 114, or source/drain region 106 or 108, that is measured post-implantation.

The dopant dosage for an area to be implanted (e.g., measured for a specific area prior to implantation) may be included in the range of approximately 1×10¹²/cm² to approximately 5×10¹⁶/cm² for the source/drain regions 106 and 108. The dopant dosage for an area to be implanted may be included in the range of approximately 1×10¹²/cm² to approximately 5×10¹²/cm² for the lightly doped implant regions 112 and 114. The dopant dosage for an area to be implanted may be included in the range of approximately 1×10⁶/cm² to approximately 1×10¹²/cm² for the well region 130. In some implementations, the dopant type for the well region 130 may be n-type, while the dopant type for the lightly doped implant regions 112 and 114, and the source/drain regions 106 and 108 may be p-type. Alternatively, the dopant type for the well region 130 may be p-type, while the dopant type for the lightly doped implant regions 112 and 114, and the source/drain regions 106 and 108, may be p-type.

A channel region 132 of an ESD protection device 102 is included in a portion of the well region 130 under the gate structure 110 and between the source/drain regions 106 and 108. In some implementations, the source/drain regions 106 and 108 are n-doped regions and the well region 130 is a p-doped region. In these implementations, the ESD protection device 102 may be referred to as an NPN (or NMOS) ESD protection device 102 in that an n-doped region/p-doped region/n-doped region arrangement is formed by the source/drain region 106, the channel region 132, and the source/drain region 108. In some implementations, the source/drain regions 106 and 108 are p-doped regions and the well region 130 is an n-doped region. In these implementations, the ESD protection device 102 may be referred to as a PNP (or PMOS) ESD protection device 102 in that a p-doped region/n-doped region/p-doped region arrangement is formed by the source/drain region 106, the channel region 132, and the source/drain region 108.

As further shown in FIG. 1B, the portions of the well region 130 in the spaces between the non-contiguous (e.g., discontinuous) lightly doped implant regions 114 may correspond to respective diffusion regions 134. The diffusion regions 134 may provide regions in the substrate 104 for diffusion of dopants from the non-contiguous (e.g., discontinuous) lightly doped implant regions 114. This enables the dopants to laterally diffuse from the non-contiguous lightly doped implant regions 114 into the diffusion regions 134, as opposed to the dopants building up along the edges of a single lightly doped implant region adjacent to the channel regions 132 under the gate structures 110. This inhibits an electric field in an ESD protection device 102 from building up at the interface between a single lightly doped implant region and the channel regions 132, which might otherwise cause premature burnout of the ESD protection device(s) 102. The quantity of the non-contiguous lightly doped implant regions 114 illustrated in FIG. 1B is an example, and other quantities are within the scope of the present disclosure.

As further shown in FIG. 1B, the source/drain contact 116 may be included on and electrically connected to the source/drain region 106, and the source/drain interconnects 118 may be included on and electrically connected to the source/drain contact 116. Similarly, the source/drain contact 120 may be included on and electrically connected to the source/drain region 108, and the source/drain interconnects 122 may be included on and electrically connected to the source/drain contact 120. In particular, the source/drain contact 120 and the associated source/drain interconnects 122 may be included on the implant segment of the source/drain region 108 at a location farthest away from each of the gate structures 110, to reduce and/or minimize the likelihood of gate-to-drain shorting. Alternatively, source/drain contact 120 is included at another location on the implant segment of the source/drain region 108.

The gate contacts 124 may be included on and electrically connected to the gate structures 110, and the gate interconnects 126 may be included on and electrically connected to the gate contacts 124. In some implementations, silicide layers 136 are included between source/drain regions 106 and the source/drain contacts 116 and/or between the source/drain region 108 and the source/drain contact 120. The silicide layers 136 may be included to reduce contact resistance between the source/drain regions 106 and the source/drain contacts 116 and/or between the source/drain region 108 and the source/drain contact 120. A silicide layer 136 may include a metal silicide such as titanium silicide (TiSi), ruthenium silicide (RuSi), and/or another suitable metal silicide material.

As further shown in FIG. 1B, the source/drain contacts 116, the source/drain interconnects 118, the source/drain contact 120, the source/drain interconnects 122, the gate contacts 124, and the gate interconnects 126 may be included in and may extend through a plurality of dielectric layers above the substrate 104. The dielectric layers may include interlayer dielectric (ILD) layers 138 and etch stop layers (ESLs) 140, among other examples. The dielectric layers and the source/drain contacts 116, the source/drain interconnects 118, the source/drain contact 120, the source/drain interconnects 122, the gate contacts 124, and the gate interconnect 126 may correspond to an interconnect layer 142 of the semiconductor device 100. The interconnect layer 142 may also be referred to as a back end region or back end of line (BEOL) region of the semiconductor device 100. The ILD layers 138 and the ESLs 140 may each include one or more dielectric materials, such as an oxide (e.g., a silicon oxide (SiOₓ) and/or another oxide material), an undoped silicate glass (USG), a boron-containing silicate glass (BSG), a fluorine-containing silicate glass (FSG), an extreme low dielectric constant (ELK) dielectric material having a dielectric constant that is less than approximately 2.5, a silicon nitride (SiₓN_{y}), silicon carbide (SiC), silicon oxynitride (SiON), and/or another suitable dielectric material.

As indicated above, FIGS. 1A and 1B are provided as examples. Other examples may differ from what is described with regard to FIGS. 1A and 1B.

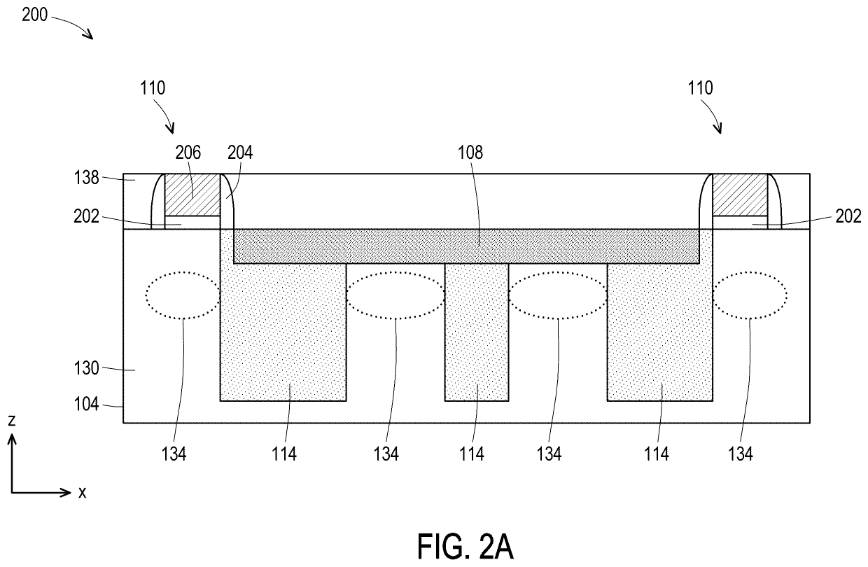

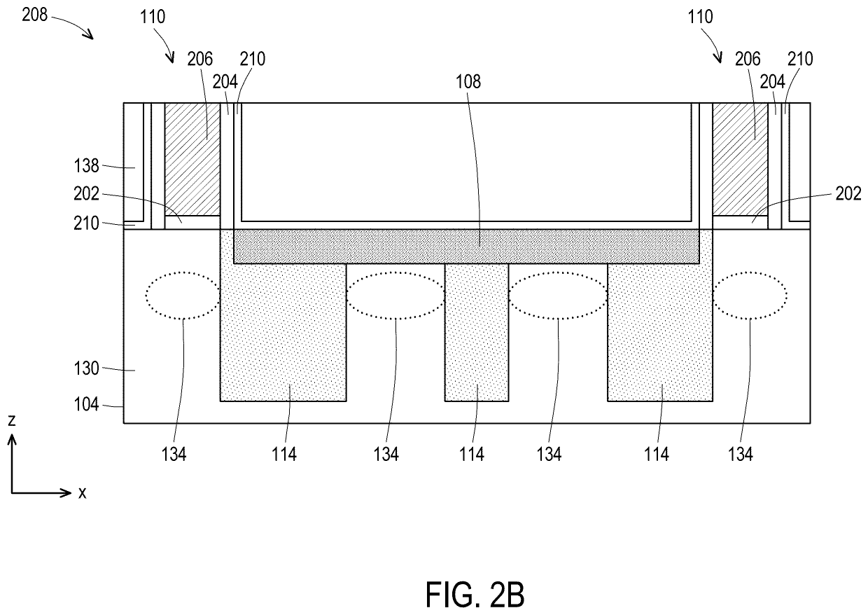

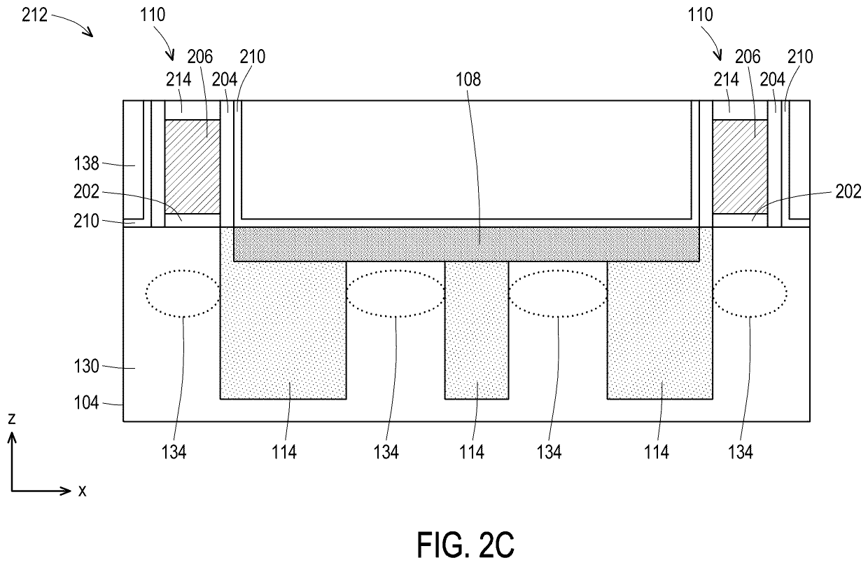

FIGS. 2A-2C are diagrams of example implementations of gate structures 110 included in an ESD protection device 102 described herein. While each of FIGS. 2A-2C illustrates a different example implementation of gate structures 110, the example implementations of gate structures 110 in FIGS. 2A-2C may be combined in various combinations for the gate structures 110. For example, two or more gates structure 110 may each include a different example implementation of a gate structure 110 in FIGS. 2A-2C.

FIG. 2A illustrates an example implementation 200 of gate structures 110 included in an ESD protection device 102. As shown in FIG. 2A, a gate structure 110 may include a gate dielectric layer 202 on the substrate 104. The gate dielectric layer 202 is included between the substrate 104 and a gate electrode 206. Sidewall spacers 204 are included on the sidewalls of the gate dielectric layer 202 and of the gate electrode 206. The sidewall spacers 204 may have a rounded or curved outer sidewall that may result from the formation process for the sidewall spacers 204. The gate dielectric layer 202 may include one or more dielectric materials, such as a low dielectric constant (low-k) dielectric material (e.g., silicon oxide (SiOₓ such as SiO₂)), a high dielectric constant (high-k) dielectric material (e.g., hafnium oxide (HfOₓ such as HfO₂)), and/or another suitable gate dielectric material. The sidewall spacers 204 may include one or

more dielectric materials such as silicon oxide (SiOₓ), silicon nitride (SiₓN_{y} such as Si₃N₄), silicon oxynitride (SiON), and/or another suitable dielectric material. The gate electrode 206 may include one or more metal materials such as tungsten (W), cobalt (Co), ruthenium (Ru), and/or titanium (Ti), among other examples. Additionally and/or alternatively, the gate electrode 206 may include one or more work function metal layers for tuning the work function of the gate electrode 206.

FIG. 2B illustrates an example implementation 208 of gate structures 110 included in an ESD protection device 102. As shown in FIG. 2B, a gate structure 110 may include a gate dielectric layer 202 on the substrate 104 and sidewall spacers 204. In the example implementation 208, the sidewalls spacers 204 have substantially straight inner and outer sidewalls. Moreover, a contact etch stop layer (CESL) 210 is included between the gate structures and the ILD layer 138. The CESL 210 may facilitate etching of recesses through the ILD layer 138 for forming of source/drain contacts 116 and 120 of the ESD protection device 102. The CESL 210 may each include one or more dielectric materials, such as a silicon oxide (SiOₓ), a silicon nitride (SiₓN_{y}), a silicon oxynitride (SiON), tetraethyl orthosilicate oxide, phosphosilicate glass (PSG), borophosphosilicate glass (BPSG), fluorinated silica glass (FSG), and/or carbon doped silicon oxide, among other examples.

FIG. 2C illustrates an example implementation 212 of gate structures included in an ESD protection device 102. As shown in FIG. 2C, the example implementation 212 of gate structures is similar to the example implementation 208 of gate structures in FIG. 2B. However, as illustrated in FIG. 2C, a capping layer 214 is included on the gate structures. The capping layer 214 may include one or more dielectric materials, such as a silicon oxide (SiOₓ), a silicon nitride (SiₓN_{y}), a silicon oxynitride (SiON), tetraethyl orthosilicate oxide, phosphosilicate glass (PSG), borophosphosilicate glass (BPSG), fluorinated silica glass (FSG), and/or carbon doped silicon oxide, among other examples.

As indicated above, FIGS. 2A-2C are provided as examples. Other examples may differ from what is described with regard to FIGS. 2A-2C.

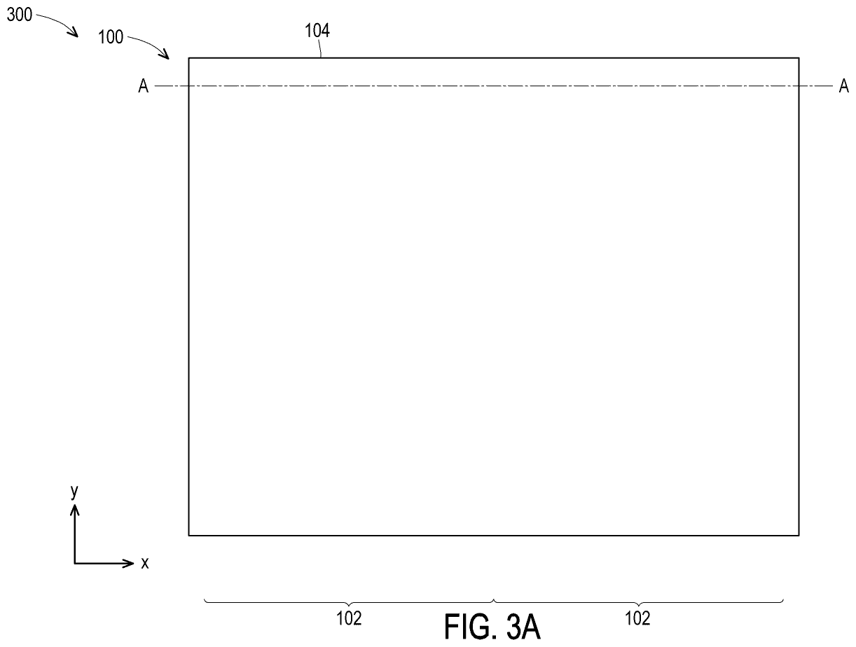

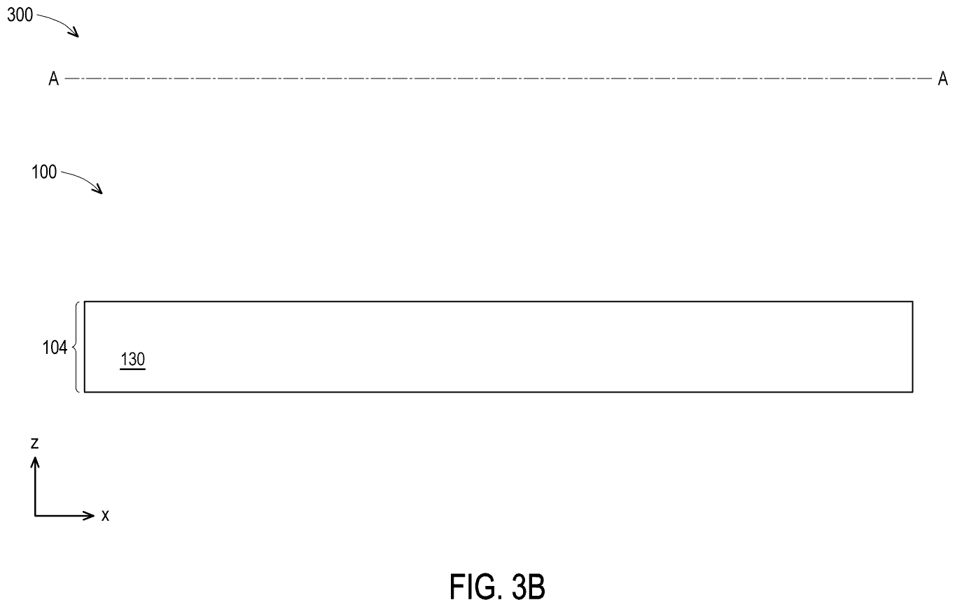

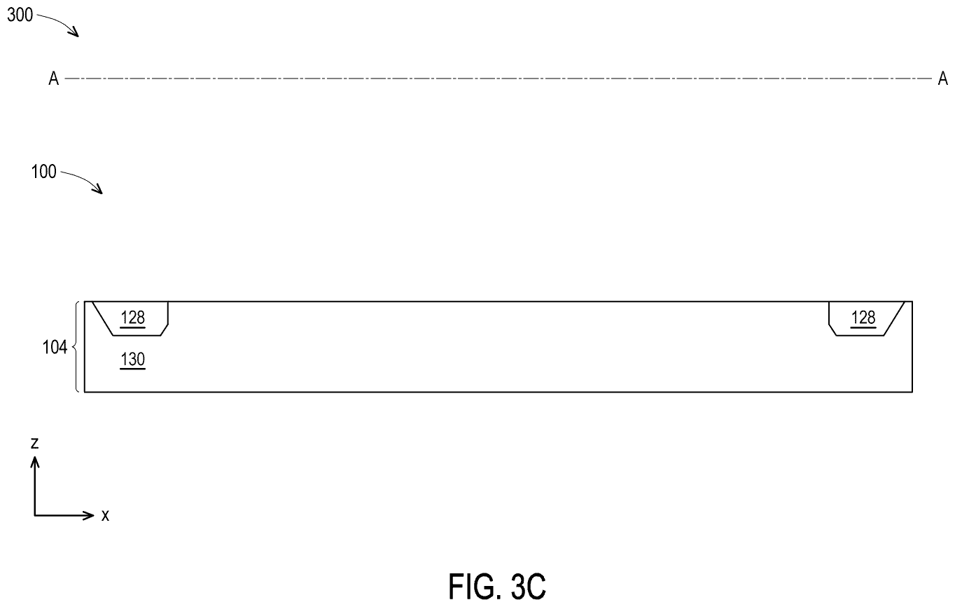

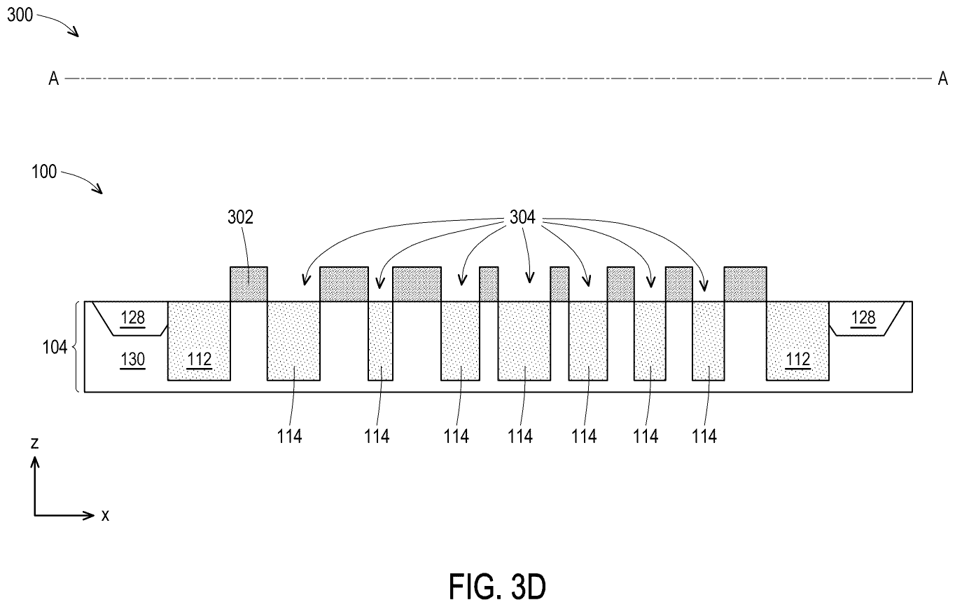

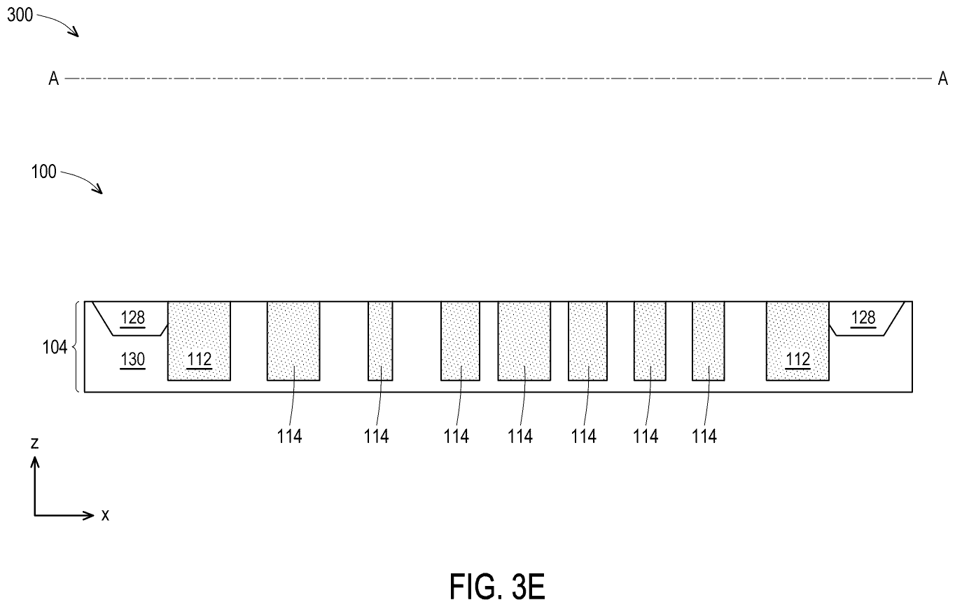

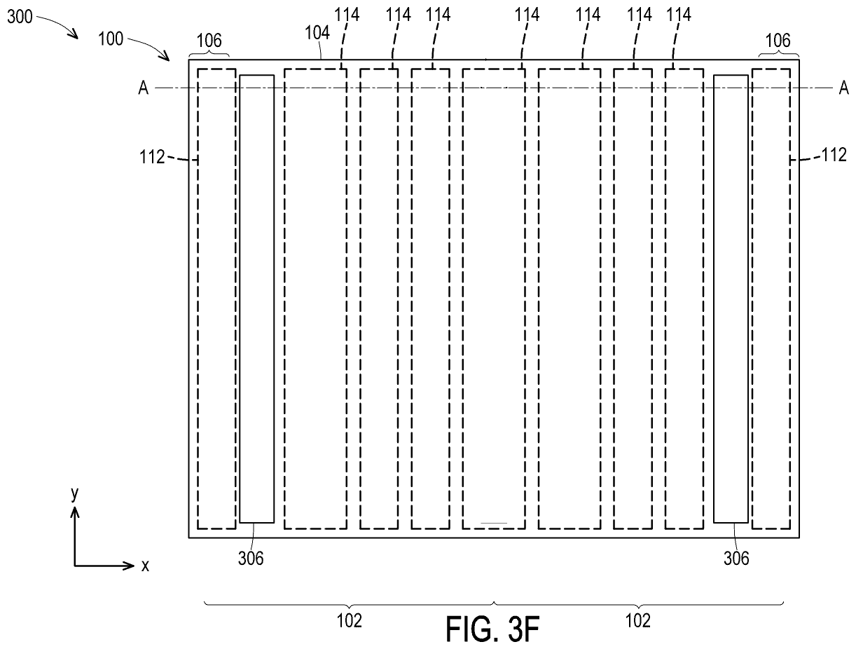

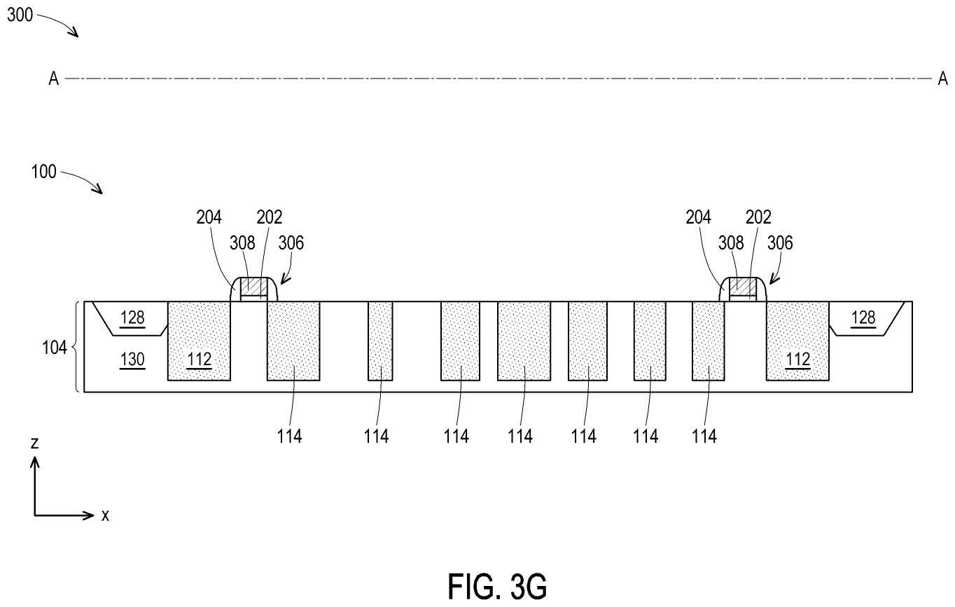

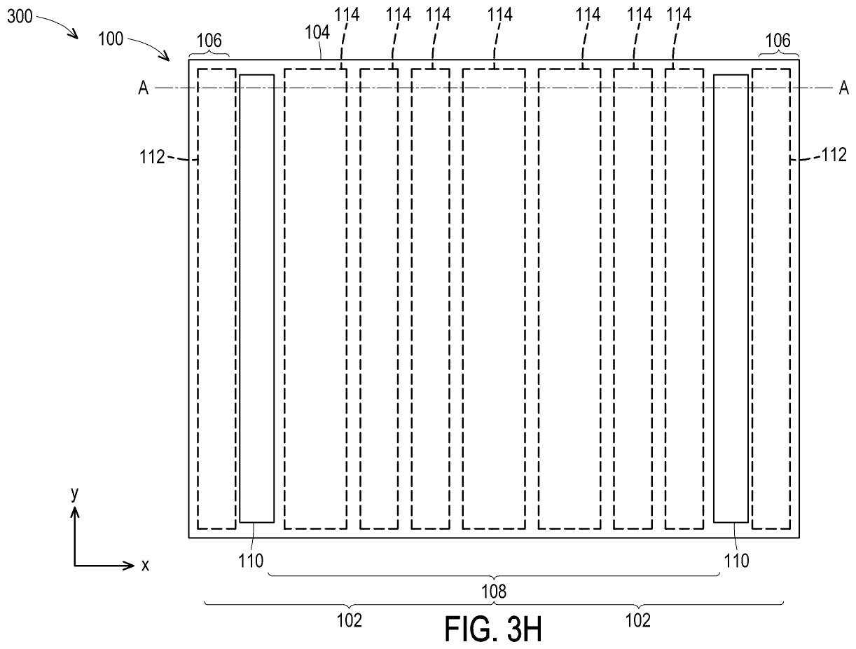

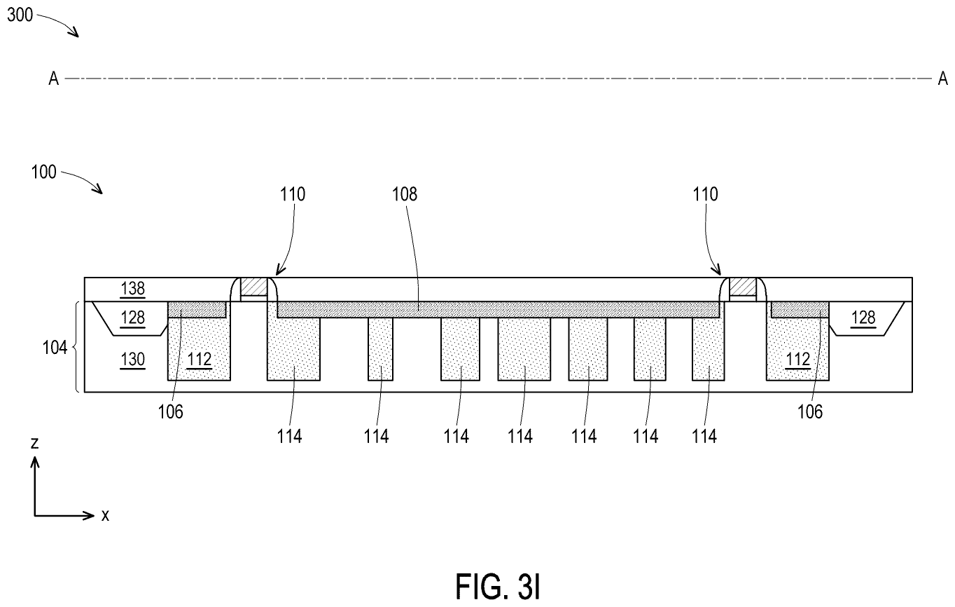

FIGS. 3A-3I are diagrams of an example implementation 300 of ESD protection devices 102 of a semiconductor device 100 described herein. In some implementations, one or more of the operations described in connection with FIGS. 3A-3I may be performed using one or more semiconductor processing tools, such as a deposition tool, an exposure tool, a developer tool, an etch tool, an ion implantation tool, and/or a planarization tool, among other examples.

Turning to FIGS. 3A and 3B, the substrate 104 may be provided. The substrate 104 may be provided as a semiconductor wafer, a semiconductor die, and/or another type of semiconductor substrate. In some implementations, the substrate 104 may be a doped substrate, such as a semiconductor substrate that is doped with one or more dopants of a first dopant type (e.g., p-type dopant, n-type dopants) to form the well region 130. In some implementations, the substrate 104 is doped using an implantation tool to form the well region 130. In some implementations, the substrate 104 is doped by diffusion and/or another doping technique.

As shown in FIG. 3C, an STI formation operation is performed to form STI regions 128 in the substrate 104. The STI regions 128 may be formed in the well region 130 and/or in another location in the substrate 104. To form the STI regions 128, recesses may be formed in the substrate 104, and the material of the STI regions 128 may be deposited in the recesses.

In some implementations, a pattern in a photoresist layer is used to etch the substrate 104 to form the recesses. In these implementations, a deposition tool is used to form the photoresist layer on the substrate 104. An exposure tool is used to expose the photoresist layer to a radiation source to pattern the photoresist layer. A developer tool is used to develop and remove portions of the photoresist layer to expose the pattern. An etch tool is used to etch the substrate 104 based on the pattern to form the recesses in the substrate 104. In some implementations, the etch operation includes a plasma etch operation, a wet chemical etch operation, and/or another type of etch operation. In some implementations, a photoresist removal tool removes the remaining portions of the photoresist layer (e.g., using a chemical stripper, plasma ashing, and/or another technique). In some implementations, a hard mask layer is used as an alternative technique for etching the substrate 104 based on a pattern.

A deposition tool may be used to deposit the material of the STI regions 128 using a physical vapor deposition (PVD) technique, an atomic layer deposition (ALD) technique, a chemical vapor deposition (CVD) technique, an oxidation operation, and/or another suitable deposition operation. In some implementations, a planarization tool is used to perform a planarization operation such as a chemical mechanical planarization (CMP) operation to planarize the STI regions 128.

As shown in FIG. 3D, one or more well implantation operations may be performed to form the lightly doped implant regions 112 and 114 in the substrate 104. The lightly doped implant regions 112 and 114 may be formed below the surface of the substrate 104. Moreover, the lightly doped implant regions 112 and 114 may be formed in the well region 130. In some implementations, an ion implantation tool is used to perform one or more ion implantation operations to form the lightly doped implant regions 112 and 114 in the substrate 104. In some implementations, an implantation mask 302 is formed on the substrate 104, a pattern 304 is formed in the implantation mask 302, and the pattern 304 in the implantation mask is used to selectively dope regions of the substrate 104 that are left exposed (e.g., not covered) by the implantation mask 302, to form the lightly doped implant regions 112 and 114. The implantation mask 302 enables the formation of the plurality of non-contiguous lightly doped implant regions 114 that are spaced apart in the substrate 104 of the semiconductor device 100. Thus, the non-contiguous lightly doped implant regions 114 are omitted from the regions of the substrate 104 under the portions of the implantation mask 302, resulting in spaces between the non-contiguous lightly doped implant regions 114. The spaces between the non-contiguous lightly doped implant regions 114 correspond to diffusion regions 134.

As shown in FIGS. 3E, 3F, and 3G, following removal of the implantation mask 302, dummy gate structures 306 are formed on the substrate 104 in positions where the gate structures 110 will be formed. More particularly, the dummy gate structures 306 may be formed on portions of the well region 130 between the lightly doped implant regions 112 and 114. The dummy gate structures 306 include the gate dielectric layer 202, the sidewall spacers 204, and a sacrificial gate electrode 308 including, for example, polycrystalline silicon (polysilicon or PO) or another material, which will be replaced with a metal gate electrode (e.g., gate electrode 206) in a replacement gate process.

As shown in FIGS. 3H and 3I, the source/drain regions 106 and 108 of the ESD protection devices 102 are formed in the substrate 104. As shown in FIG. 3H, the source/drain regions 106 may each be formed in a lightly doped implant region 112, and the source/drain region 108 may be formed in the plurality of non-contiguous (e.g., discontinuous) lightly doped implant regions 114. Using the dummy gate structures 306 as a self-aligned implant mask, the exposed regions of the substrate 104, and of the lightly doped implant regions 112 and 114, are selectively doped to form the implant segments of the source/drain regions 106 and of the source/drain region 108. This enables well regions in the substrate 104 to be formed under the dummy gate structures 306. In addition, portions of one or more of the lightly doped implant regions 112 and/or 114 may be under part of the dummy gate structures 306 (e.g., under the sidewall spacers 204), so that the overlapped portions of the lightly doped implant regions 112 and/or 114 are masked from ion implantation used to form the source/drain regions 106 and 108.

As shown in FIG. 3I, following ion implantation to form the source/drain regions 106 and 108, an ILD layer 138 is formed on the substrate 104, and a replacement gate process to replace the sacrificial gate electrodes 308 with gate electrodes 206 is performed, thereby forming the gate structures 110. An etch tool may be used to etch the sacrificial gate electrodes 308, and a deposition tool may be used to deposit the gate electrodes 206 in place of the sacrificial gate electrodes 308. A planarization process such as, for example, chemical mechanical planarization (CMP) may be performed following the deposition of the gate electrodes 206 to remove excess metal material from on top of the ILD layer 138.

As indicated above, FIGS. 3A-3I are provided as examples. Other examples may differ from what is described with regard to FIGS. 3A-3I.

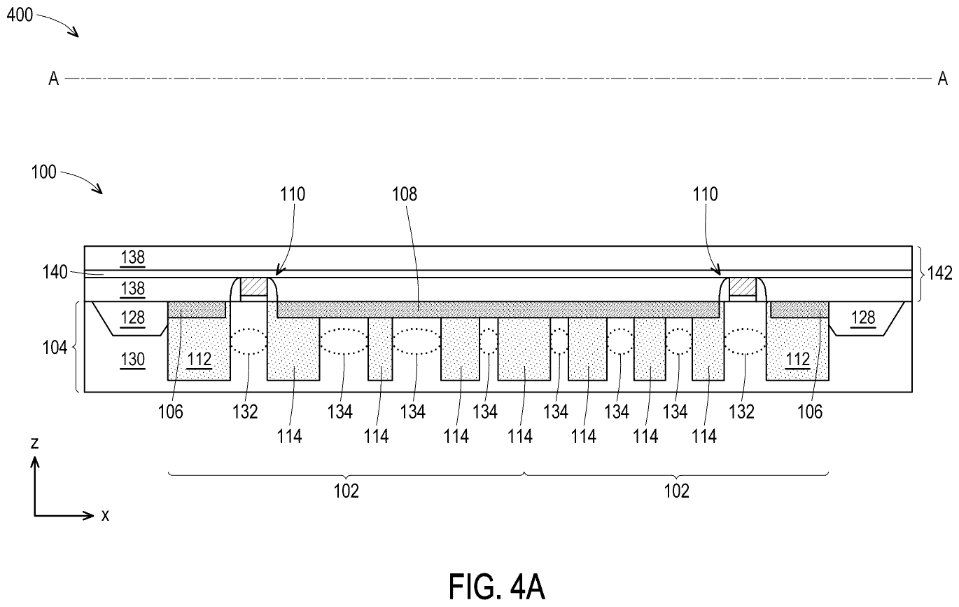

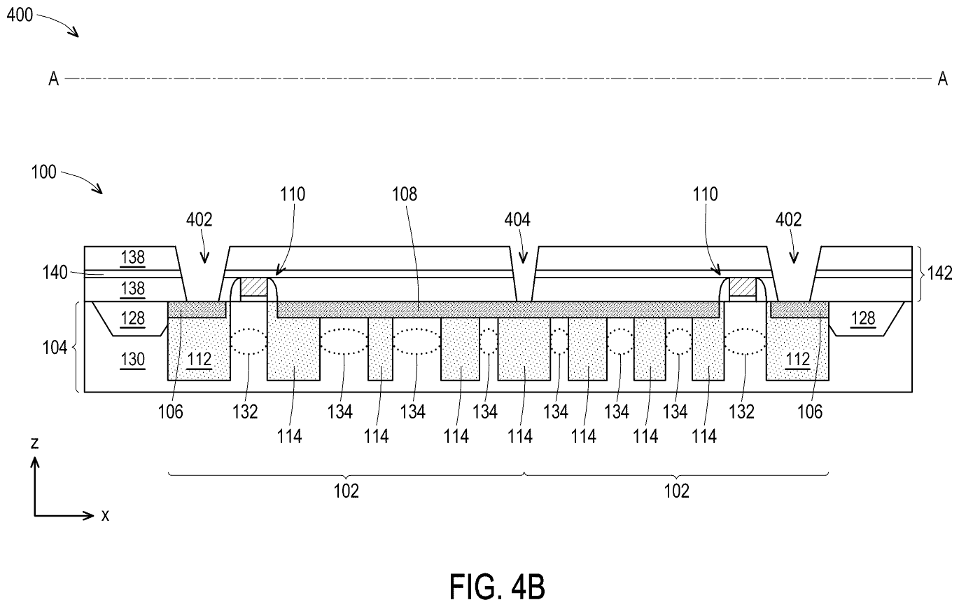

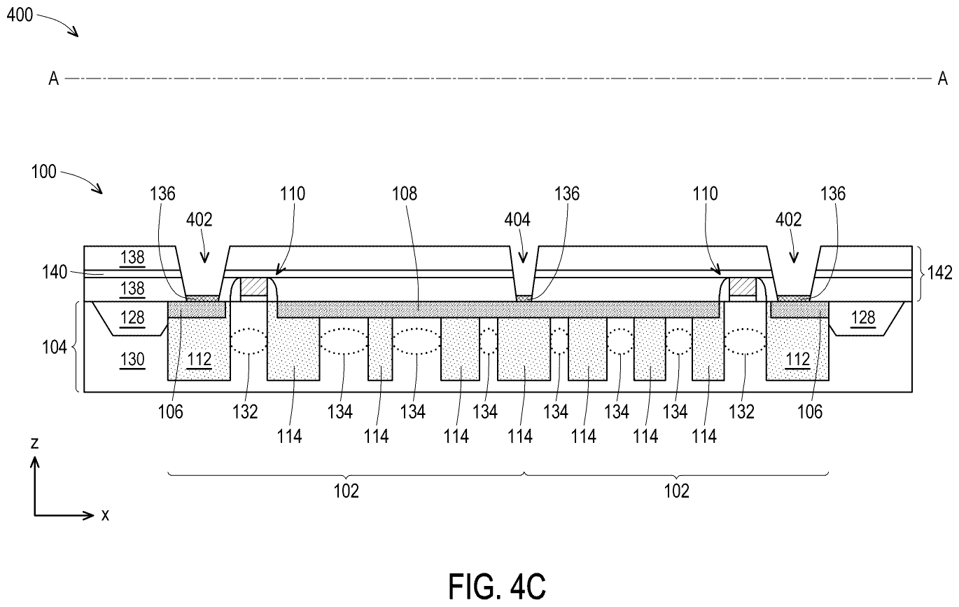

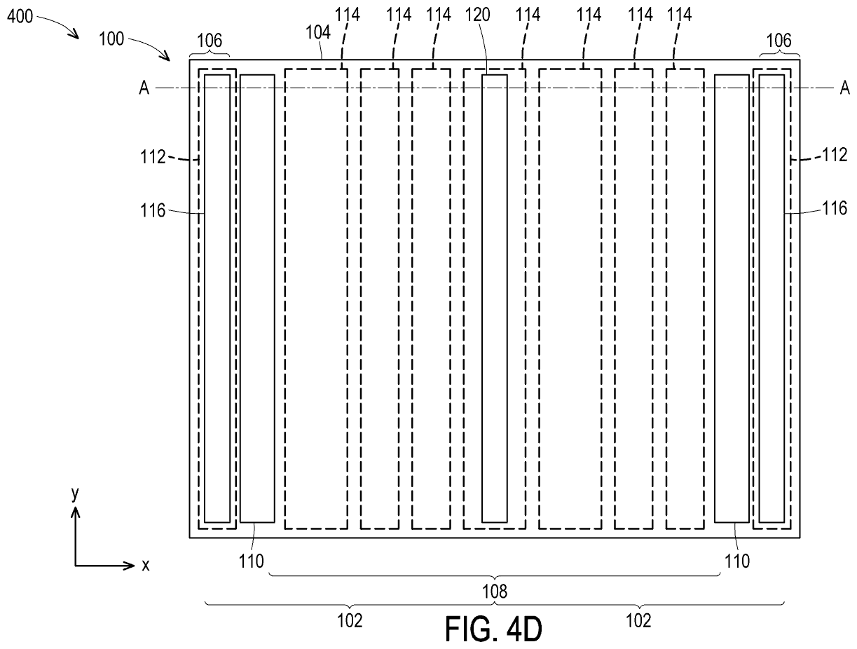

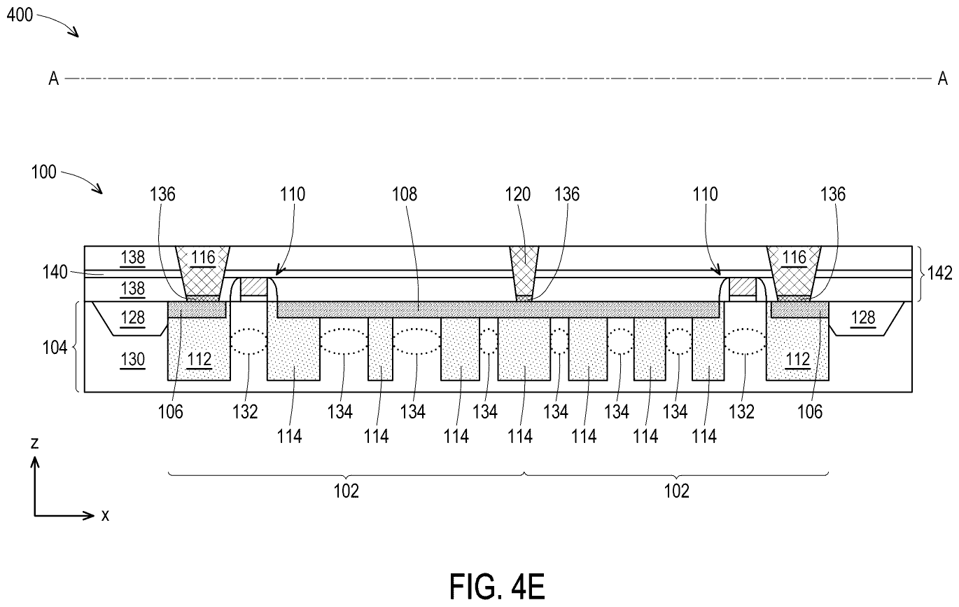

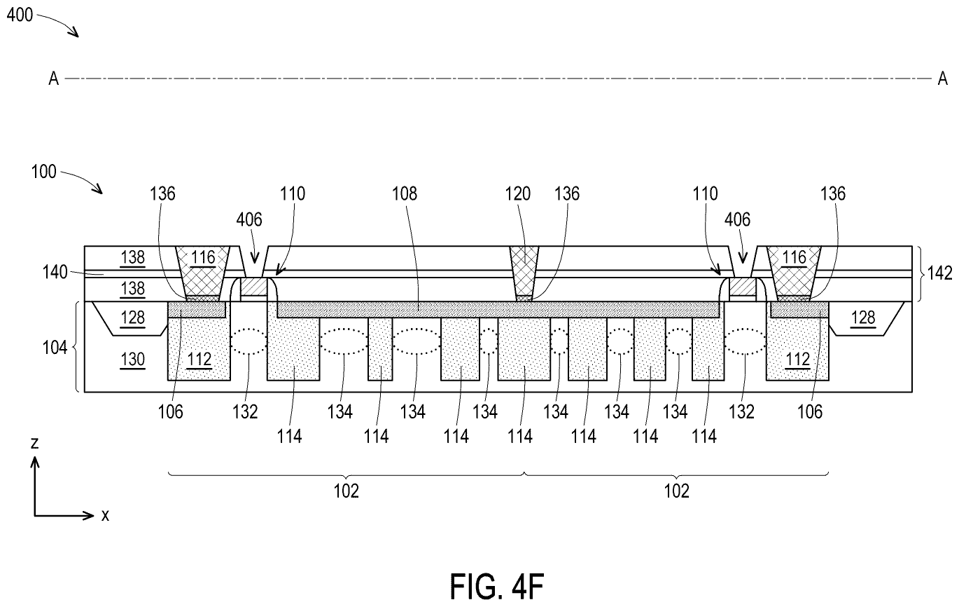

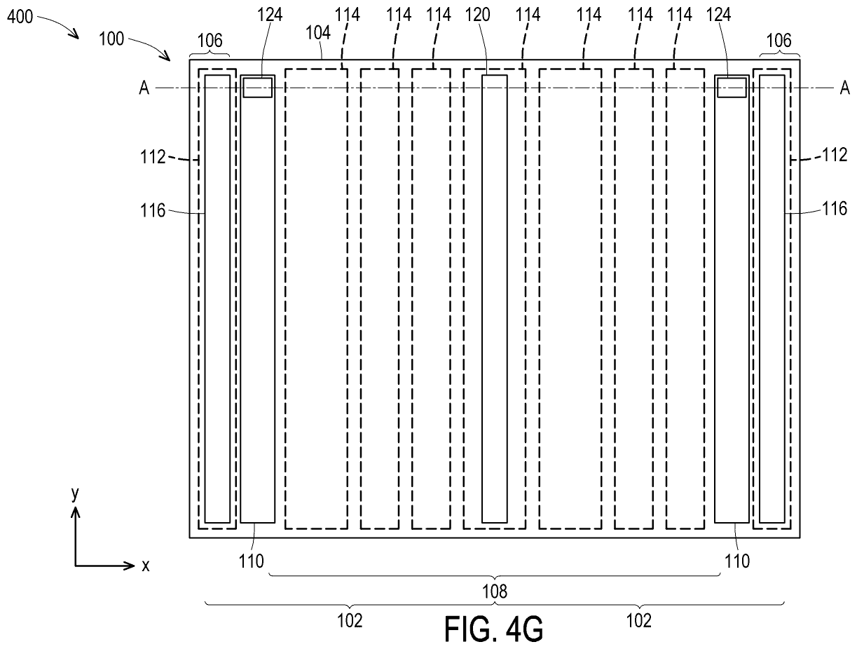

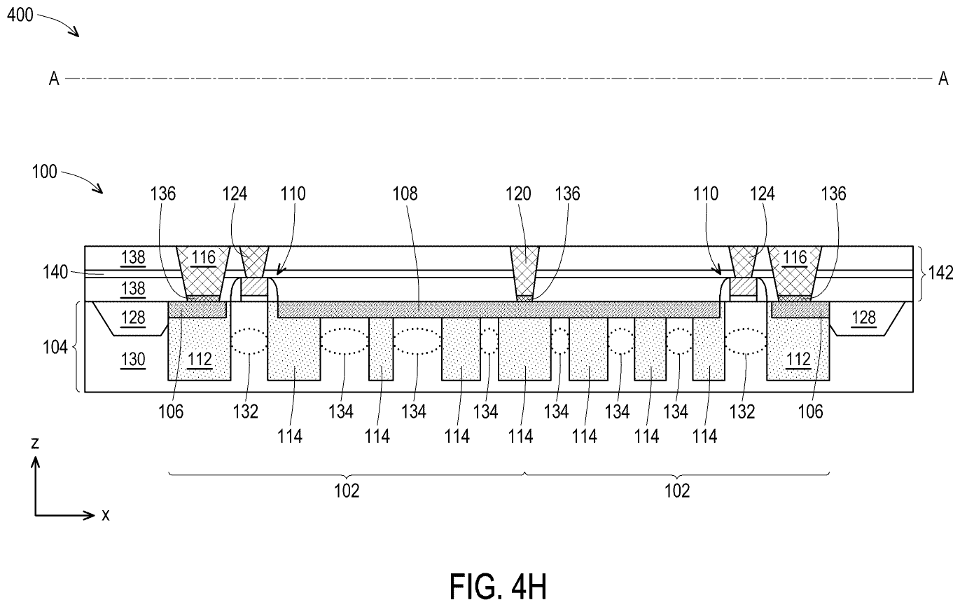

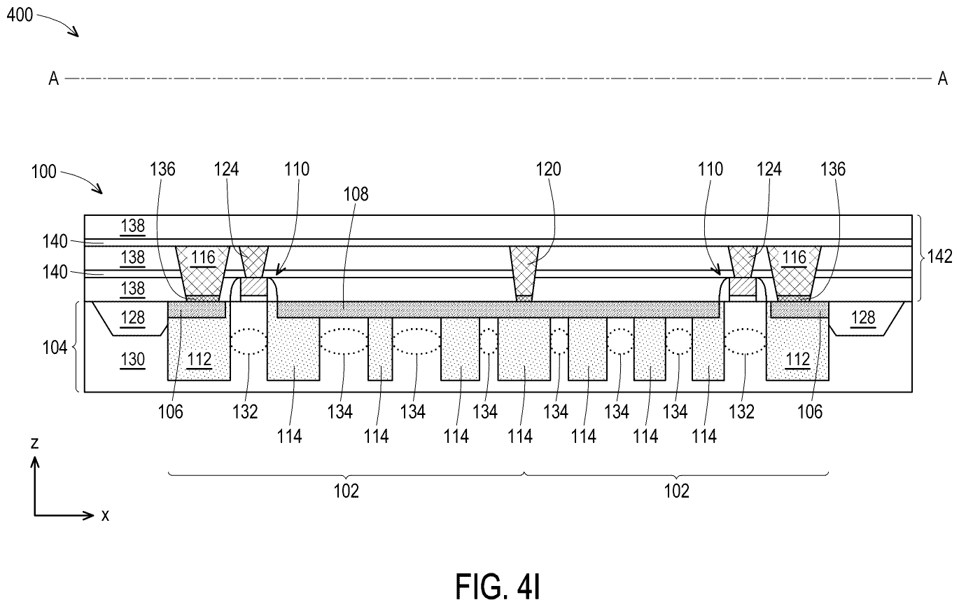

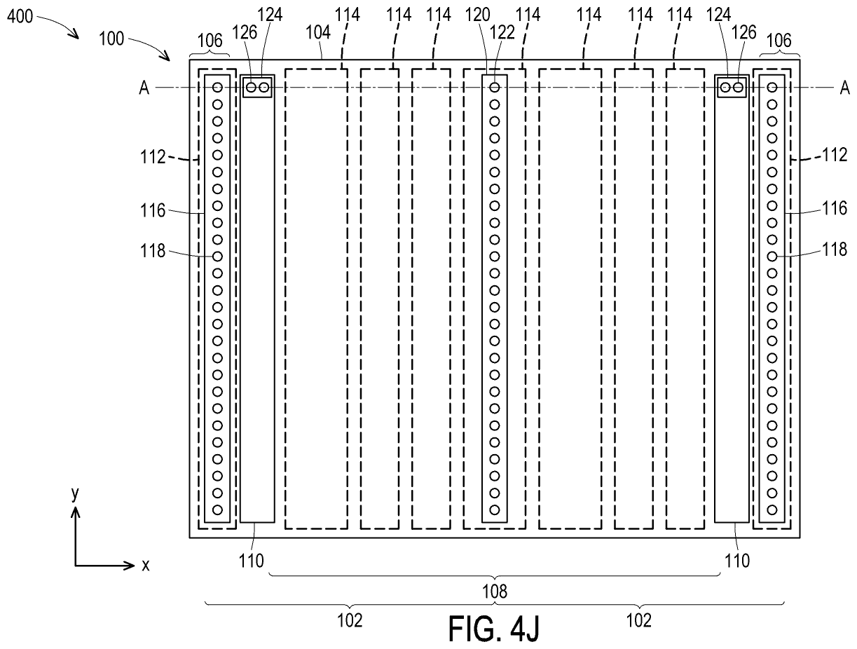

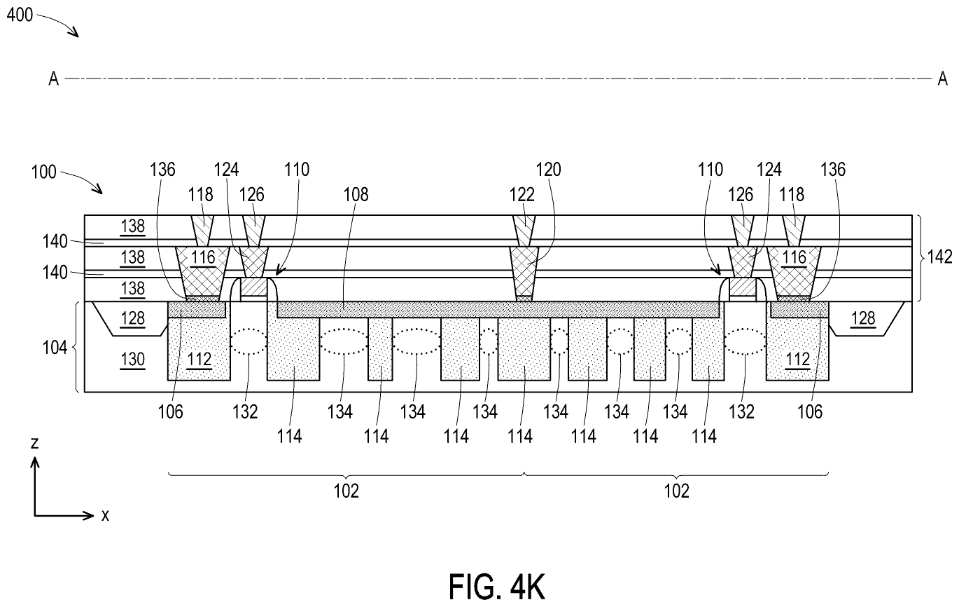

FIGS. 4A-4K are diagrams of an example implementation 400 of forming an interconnect layer 142 of a semiconductor device 100 described herein. In some implementations, one or more of the semiconductor processing operations described in connection with FIGS. 4A-4K may be performed after one or more operations described in connection with FIGS. 3A-3I. In some implementations, one or more of the operations described in connection with FIGS. 4A-4K may be performed using one or more semiconductor processing tools, such as a deposition tool, an exposure tool, a developer tool, an etch tool, and/or a planarization tool, among other examples.

As shown in FIG. 4A, one or more ILD layers 138 and one or more ESLs 140 of the interconnect layer 142 may be formed above the substrate 104 and over the gate structures 110 of the ESD protection devices 102. The ILD layer(s) 138 and the ESL(s) 140 may be deposited in an alternating manner in the z-direction in the interconnect layer 142.

A deposition tool may be used to deposit an ILD layer 138 using a PVD technique, an ALD technique, a CVD technique, an oxidation technique, and/or another suitable deposition technique. An ILD layer 138 may be deposited in one or more deposition operations. In some implementations, a planarization tool may be used to perform a planarization operation (e.g., a CMP operation) to planarize an ILD layer 138 after the ILD layer 138 is deposited.

A deposition tool may be used to deposit an ESL 140 using a PVD technique, an ALD technique, a CVD technique, an oxidation technique, and/or another suitable deposition technique. An ESL 140 may be deposited in one or more deposition operations. In some implementations, a planarization tool may be used to perform a planarization operation (e.g., a CMP operation) to planarize an ESL 140 after the ESL 140 is deposited.

As shown in FIG. 4B, recesses 402 and 404 may be formed through the ILD layer(s) 138 and the ESL(s) 140. The recesses 402 may be formed over the source/drain regions 106 of the ESD protection devices 102, and the recess 404 may be formed over the source/drain region 108. In particular, a recess 404 may be formed over a portion of the implant segment of the source/drain region 108 that is located farthest away from both of the gate structures 110. Alternatively, the recess 404 may be formed over another portion of the implant segment of the source/drain region 108.

In some implementations, a pattern in a photoresist layer is used to etch the ILD layer(s) 138 and the ESL(s) 140 to form the recesses 402 and 404. In these implementations, a deposition tool may be used to form the photoresist layer on the topmost ILD layer 138. An exposure tool may be used to expose the photoresist layer to a radiation source to pattern the photoresist layer. A developer tool may be used to develop and remove portions of the photoresist layer to expose the pattern. An etch tool may be used to etch the ILD layer(s) 138 and the ESL(s) 140 based on the pattern to form the recesses 402 and 404. In some implementations, the etch operation includes a dry etch operation (e.g., a plasma-based etch operation, a gas-based etch operation), a wet chemical etch operation, and/or another type of etch operation. In some implementations, a photoresist removal tool may be used to remove the remaining portions of the photoresist layer (e.g., using a chemical stripper, plasma ashing, and/or another technique). In some implementations, a hard mask layer is used as an alternative technique for forming the recesses 402 and 404 based on a pattern.

As shown in FIG. 4C, a salicide process (e.g., a self-aligned silicide process) may be performed to form silicide layers 136 on the tops of the source/drain regions 106 at the bottoms of the recesses 402, and to form a silicide layer 136 on the top of the source/drain region 108 (e.g., the tops of the implant segment) at the bottoms of the recess 404. The salicide process may include depositing a metal layer such as titanium (Ti) on the semiconductor device 100, including in the recesses 402 and 404. The metal layer is then annealed. The salicide process may be self-aligned in that the annealing of the metal layer causes the metal layer to selectively react with the semiconductor material (e.g., silicon (Si)) of the source/drain regions 106 and 108, thereby forming the silicide layers 136 at the bottoms of the recesses 402 and 404. Unreacted material from the metal layer on other parts of the semiconductor device 100 may be subsequently removed (e.g., by etching and/or another suitable technique).

As shown in FIG. 4D, the source/drain contacts 116 are formed on the source/drain regions 106, and the source/drain contact 120 is formed on the source/drain region 108. A source/drain contact 116 of an ESD protection device 102 may be formed adjacent to a first side of a gate structure 110 of the ESD protection device 102, and a source/drain contact 120 of the ESD protection device 102 may be formed on an opposing second side of the gate structure 110.

As shown in FIG. 4E, the source/drain contacts 116 are formed on the silicide layers 136 in the recesses 402 such that the source/drain contacts 116 are located above the source/drain regions 106. The source/drain contact 120 is formed on the silicide layer 136 in the recess 404 such that the source/drain contact 120 is located above the implant segment of the source/drain region 108.

A deposition tool may be used to deposit the source/drain contacts 116 and 120 using a CVD technique, a PVD technique, an ALD technique, an electroplating technique, and/or another suitable deposition technique. The source/drain contacts 116 and 120 may be deposited in one or more deposition operations. In some implementations, a seed layer is first deposited, and a source/drain contact 116 or 120 is deposited on the seed layer. In some implementations, a liner (e.g., an adhesion liner, a barrier liner) is first deposited, and a source/drain contact 116 or 120 is deposited on the liner. In some implementations, a planarization tool is used to perform a planarization operation (e.g., a CMP operation) to planarize the source/drain contacts 116 and 120 after the source/drain contacts 116 and 120 are deposited.

As shown in FIG. 4F, recesses 406 may be formed through the ILD layer(s) 138 and the ESL(s) 140. The recesses 406 may be formed over the gate structures 110 of the ESD protection devices 102. In some implementations, a pattern in a photoresist layer is used to etch the ILD layer(s) 138 and the ESL(s) 140 to form the recesses 406. In these implementations, a deposition tool may be used to form the photoresist layer on the topmost ILD layer 138. An exposure tool may be used to expose the photoresist layer to a radiation source to pattern the photoresist layer. A developer tool may be used to develop and remove portions of the photoresist layer to expose the pattern. An etch tool may be used to etch the ILD layer(s) 138 and the ESL(s) 140 based on the pattern to form the recesses 406. In some implementations, the etch operation includes a dry etch operation (e.g., a plasma-based etch operation, a gas-based etch operation), a wet chemical etch operation, and/or another type of etch operation. In some implementations, a photoresist removal tool may be used to remove the remaining portions of the photoresist layer (e.g., using a chemical stripper, plasma ashing, and/or another technique). In some implementations, a hard mask layer is used as an alternative technique for forming the recesses 406 based on a pattern.

As shown in FIG. 4G, gate contacts 124 may be formed on the gate structures 110 of the ESD protection devices 102. In some implementations, the gate contacts 124 are formed at ends of the active gate structures 110. In some implementations, the gate contacts 124 are formed at another location on the active gate structures 110.

As shown in FIG. 4H, the gate contacts 124 are formed in the recesses 406 such that the gate contacts 124 land on the active gate structures 110 of the ESD protection devices 102. A deposition tool may be used to deposit the gate contacts 124 using a CVD technique, a PVD technique, an ALD technique, an electroplating technique, and/or another suitable deposition technique. The gate contacts 124 may be deposited in one or more deposition operations. In some implementations, a seed layer is first deposited, and a gate contact 124 is deposited on the seed layer. In some implementations, a liner (e.g., an adhesion liner, a barrier liner) is first deposited, and a gate contact 124 are deposited on the liner. In some implementations, a planarization tool is used to perform a planarization operation (e.g., a CMP operation) to planarize the gate contacts 124 after the gate contacts 124 are deposited.

As shown in FIG. 4I, one or more additional ILD layers 138 and one or more additional ESLs 140 of the interconnect layer 142 may be formed. The additional ILD layer(s) 138 and the additional ESL(s) 140 may be deposited in an alternating manner in the z-direction in the interconnect layer 142.

A deposition tool may be used to deposit an ILD layer 138 using a PVD technique, an ALD technique, a CVD technique, an oxidation technique, and/or another suitable deposition technique. An ILD layer 138 may be deposited in one or more deposition operations. In some implementations, a planarization tool may be used to perform a planarization operation (e.g., a CMP operation) to planarize an ILD layer 138 after the ILD layer 138 is deposited.

A deposition tool may be used to deposit an ESL 140 using a PVD technique, an ALD technique, a CVD technique, an oxidation technique, and/or another suitable deposition technique. An ESL 140 may be deposited in one or more deposition operations. In some implementations, a planarization tool may be used to perform a planarization operation (e.g., a CMP operation) to planarize an ESL 140 after the ESL 140 is deposited.

As shown in FIGS. 4J and 4K, source/drain interconnects 118 may be formed on the source/drain contacts 116, source/drain interconnects 122 may be formed on the source/drain contact 120, and gate interconnects 126 may be formed on the gate contacts 124.

Recesses may be formed through the additional ILD layer(s) 138 and the additional ESL(s) 140 for the source/drain interconnects 118, the source/drain interconnects 122, and the gate interconnects 126. The recesses may be formed over the source/drain contacts 116, over the source/drain contact 120, and over the gate contacts 124. In some implementations, a pattern in a photoresist layer is used to etch the ILD layer(s) 138 and the ESL(s) 140 to form the recesses. In these implementations, a deposition tool may be used to form the photoresist layer on the topmost ILD layer 138. An exposure tool may be used to expose the photoresist layer to a radiation source to pattern the photoresist layer. A developer tool may be used to develop and remove portions of the photoresist layer to expose the pattern. An etch tool may be used to etch the ILD layer(s) 138 and the ESL(s) 140 based on the pattern to form the recesses. In some implementations, the etch operation includes a dry etch operation (e.g., a plasma-based etch operation, a gas-based etch operation), a wet chemical etch operation, and/or another type of etch operation. In some implementations, a photoresist removal tool may be used to remove the remaining portions of the photoresist layer (e.g., using a chemical stripper, plasma ashing, and/or another technique). In some implementations, a hard mask layer is used as an alternative technique for forming the recesses based on a pattern.

The source/drain interconnects 118 may be formed in recesses such that the source/drain interconnects 118 land on the source/drain contacts 116. The source/drain interconnects 122 may be formed in recesses such that the source/drain interconnects 122 land on the source/drain contact 120. The gate interconnects 126 may be formed in recesses such that the gate interconnects 126 land on the gate contacts 124.

A deposition tool may be used to deposit the source/drain interconnects 118, the source/drain interconnects 122, and the gate interconnects 126 using a CVD technique, a PVD technique, an ALD technique, an electroplating technique, and/or another suitable deposition technique. The source/drain interconnects 118, the source/drain interconnects 122, and the gate interconnects 126 may be deposited in one or more deposition operations. In some implementations, a seed layer is first deposited, and a source/drain interconnect 118, a source/drain interconnect 122, or a gate interconnect 126 is deposited on the seed layer. In some implementations, a liner (e.g., an adhesion liner, a barrier liner) is first deposited, and a source/drain interconnect 118, a source/drain interconnect 122, or a gate interconnect 126 is deposited on the liner. In some implementations, a planarization tool is used to perform a planarization operation (e.g., a CMP operation) to planarize the source/drain interconnects 118, the source/drain interconnects 122, and the gate interconnects 126 after the source/drain interconnects 118, the source/drain interconnects 122, and the gate interconnects 126 are deposited.

As indicated above, FIGS. 4A-4K are provided as examples. Other examples may differ from what is described with regard to FIGS. 4A-4K.

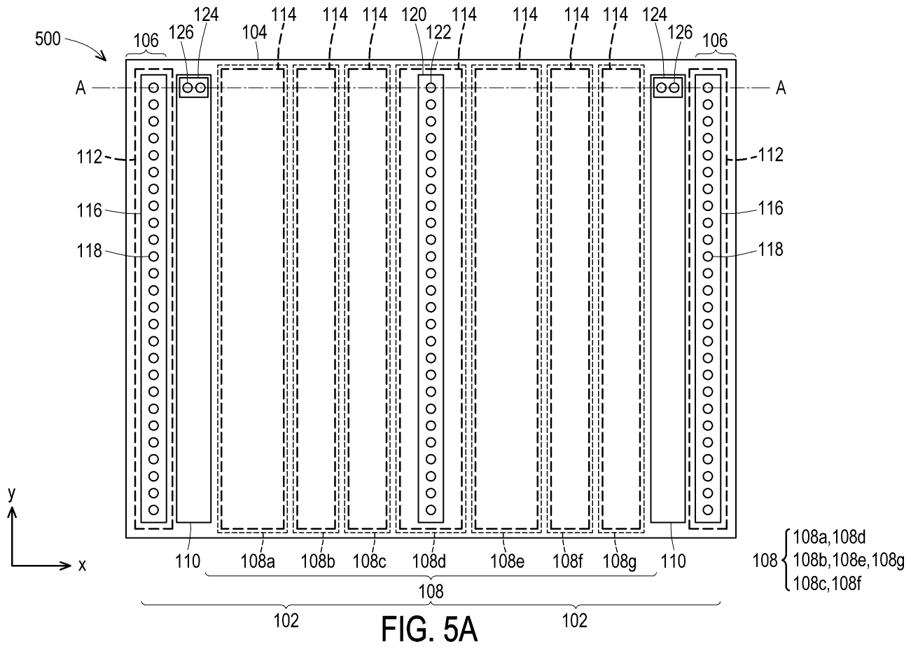

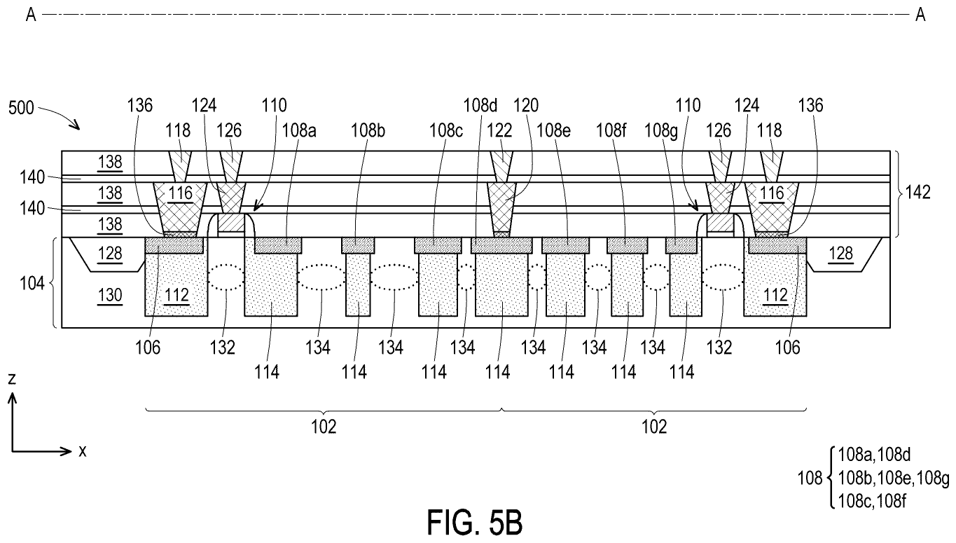

FIGS. 5A and 5B are diagrams of an example semiconductor device 500 described herein. FIG. 5A illustrates a top view of the semiconductor device 100. As shown in FIG. 5A, the semiconductor device 100 includes one or more ESD protection devices 102. One or more of the semiconductor devices 500 may be included in another semiconductor device, such as a semiconductor device 1000 of FIG. 10, to provide ESD protection for integrated circuit devices of the other semiconductor device.

As shown in FIGS. 5A and 5B, the semiconductor device 500 is similar to the semiconductor device 100 described in connection with FIGS. 1A and 1B. However, unlike the semiconductor device 100, the semiconductor device 500 includes a source/drain region 108 having a plurality of non-contiguous (e.g., discontinuous) implant segments 108a, 108b, 108c, 108d, 108e, 108f, and 108g instead of a continuous implant segment.

The source/drain region 106 and the non-contiguous implant segments 108a-108g may include the same dopant type, which may be the same dopant type as the lightly doped implant regions 112 and 114. For example, the source/drain region 106 and the non-contiguous implant segments 108a-108g may each include n-type dopants such as phosphorous (P), arsenic (As), bismuth (Bi), and/or stibium (Sb), among other examples. However, the dopant concentration in the source/drain region 106, and in the non-contiguous implant segments 108a-108g of the source/drain region 108, may be greater than the dopant concentration in the lightly doped implant regions 112 and 114.

The non-contiguous implant segments 108a-108g are spaced apart from each other along the x-direction (e.g., a direction along a top surface of the substrate 104) with respective portions of the well region 130 in the spaces between the non-contiguous implant segments 108a-108g. The spaces between adjacent lightly doped implant regions 114 and between adjacent non-contiguous implant segments (e.g., between implant segments 108a and 108b, between implant segments 108b and 108c, between implant segments 108c and 108d, etc.) provide areas in the substrate 104 in which dopants from the non-contiguous implant segments 108a-108g and from the non-contiguous lightly doped implant regions 114 may diffuse. Thus, the dopants, which may have been added during, for example, manufacturing operations for the semiconductor device 100, diffuse into the substrate 104 across a greater area of the substrate 104 than if the lightly doped implant regions 114 and/or the source/drain region 108 were not divided into separate regions. As a result, the dopant concentration from the lightly doped implant regions 114 and/or from the non-contiguous implant segments 108a-108g may be reduced in the substrate 104. This reduces the build-up and concentration of dopants near gate structures 110, which reduces the strength of the electric field near the gate structures 110. The reduced strength of the electric field near the gate structures lessens the damage caused to the ESD protection devices 102 across multiple ESD events, thereby increasing the operational life of the ESD protection devices 102.

The non-contiguous implant segments 108a-108g may extend in the x-direction through top portions of respective ones of the plurality of non-contiguous lightly doped implant regions 114. Some of the non-contiguous implant segments 108a-108g may extend into top portions of the well region 130, while other ones of the non-contiguous implant segments (e.g., implant segments 108a and 108g) may not necessarily extend in the x-direction through an entire top portion of a lightly doped implant region 114. The plurality of non-contiguous implant segments 108a-108g are located between an edge of a first gate structure 110 and an edge of a second gate structure 110. In some implementations, the two gate structures 110 respectively correspond to two ESD protection devices 102 and share the source/drain region 108. Alternatively, the two gate structures 110 correspond to the same ESD protection device 102 and share the source/drain region 108.

Portions of the well region 130 in the spaces between the non-contiguous (e.g., discontinuous) lightly doped implant regions 114, and between the non-contiguous (e.g., discontinuous) implant segments 108a-108g, correspond to respective diffusion regions 134. The diffusion regions 134 provide regions in the substrate 104 for diffusion of dopants from the non-contiguous (e.g., discontinuous) lightly doped implant regions 114 and implant segments 108a-108g. This enables the dopants to laterally diffuse from the non-contiguous lightly doped implant regions 114 and from the non-contiguous implant segments 108a-108g into the diffusion regions 134, as opposed to the dopants building up along the edges of a single lightly doped implant region adjacent to the channel regions 132 under the gate structures 110. This inhibits an electric field in an ESD protection device 102 from building up at the interface between a single lightly doped implant region and the channel regions 132, which might otherwise cause premature burnout of the ESD protection device(s) 102. The quantity of the non-contiguous (e.g., discontinuous) implant segments 108a-108g illustrated in FIG. 5B is an example, and other quantities are within the scope of the present disclosure.

As further shown in FIG. 5B, the source/drain contact 120 may be included on and electrically connected to the source/drain region 108, and the source/drain interconnects 122 may be included on and electrically connected to the source/drain contact 120. In particular, the source/drain contact 120 and the associated source/drain interconnects 122 may be included on the implant segment 108d at a location farthest away from each of the gate structures 110, to reduce and/or minimize the likelihood of gate-to-drain shorting. Alternatively, source/drain contact 120 is included on another implant segment of the source/drain region 108. In particular, the source/drain contact 120 and the associated source/drain interconnects 122 may be included on another implant segment of the source/drain region 108, such as the implant segment 108a or the implant segment 108b, among other examples.

As indicated above, FIGS. 5A and 5B are provided as examples. Other examples may differ from what is described with regard to FIGS. 5A and 5B.

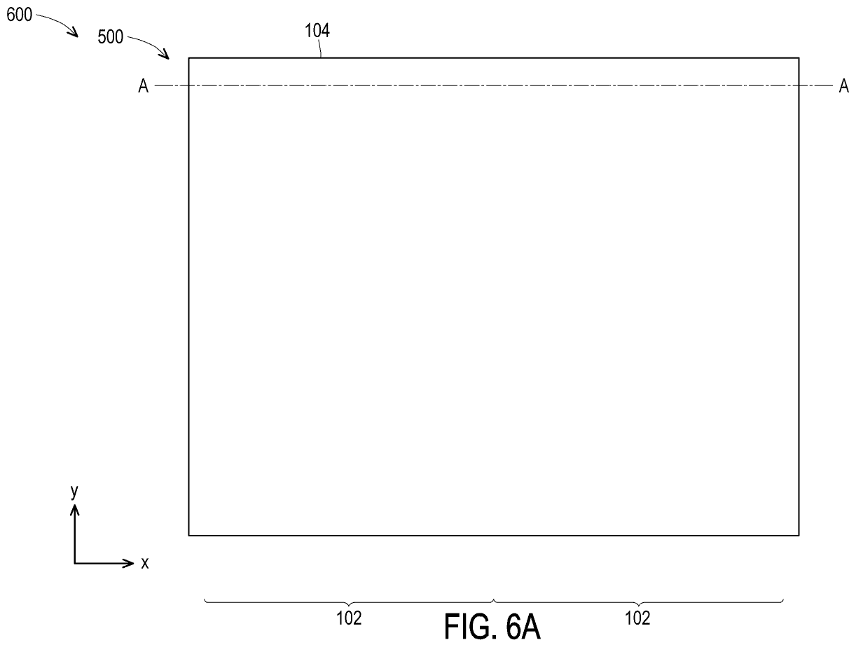

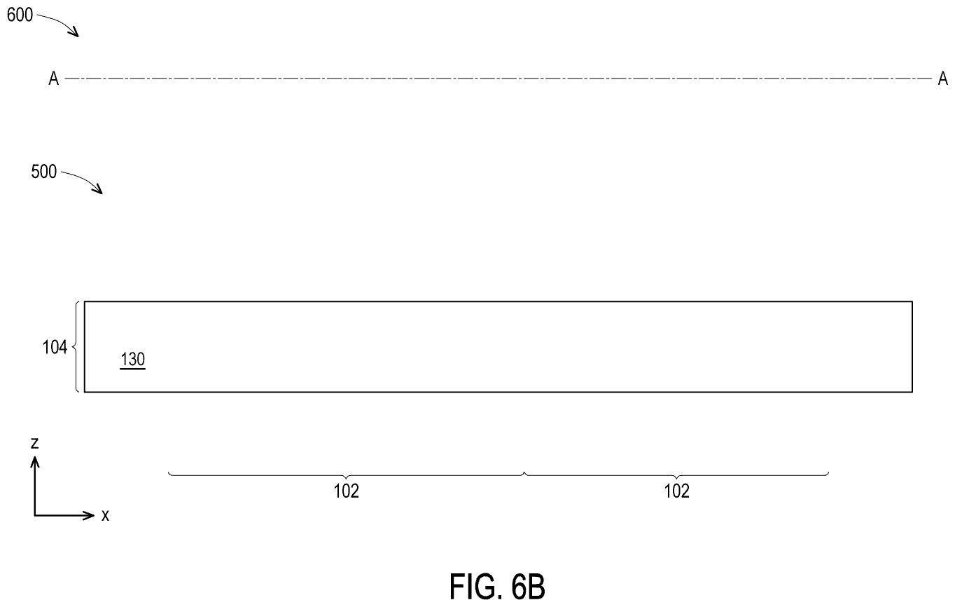

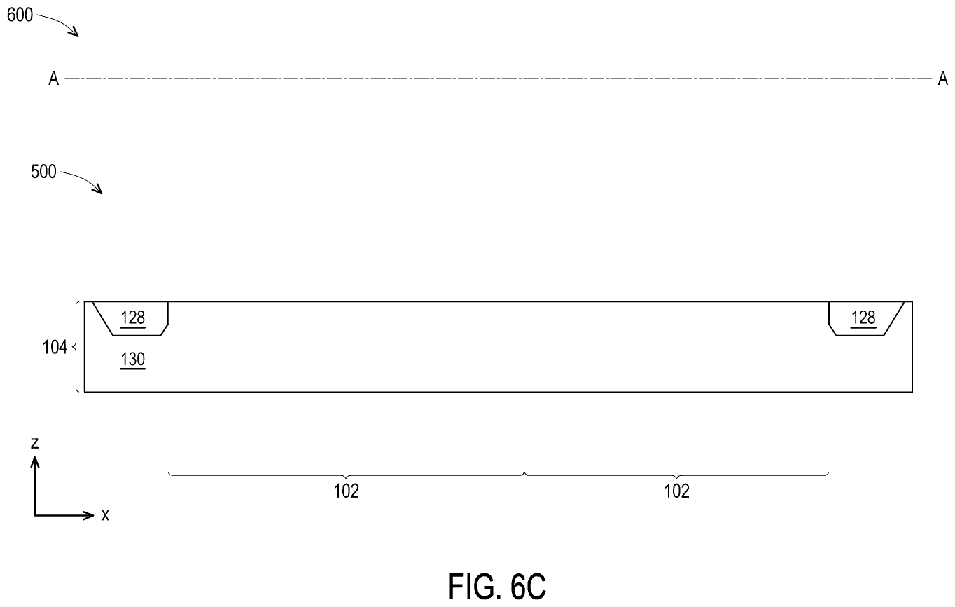

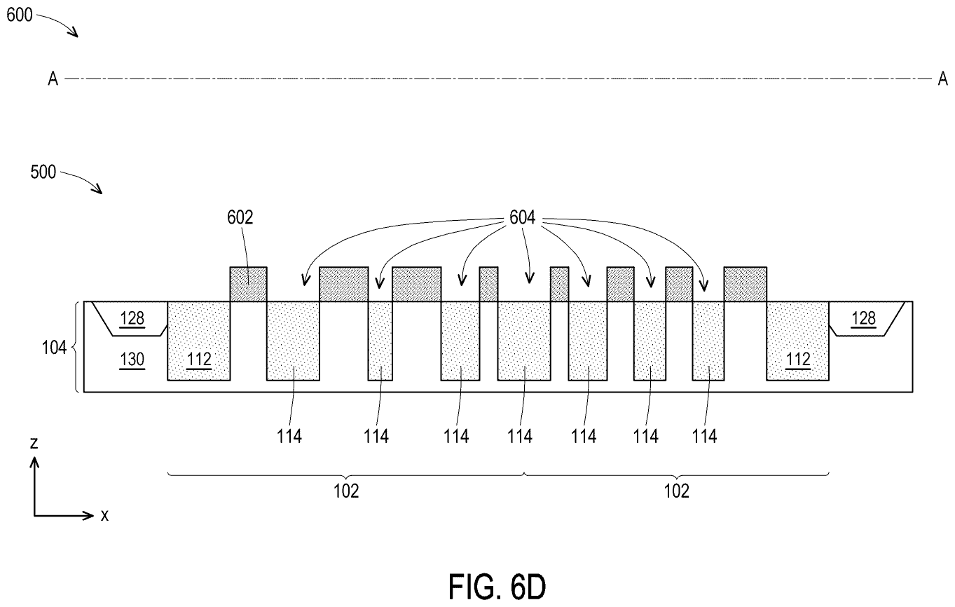

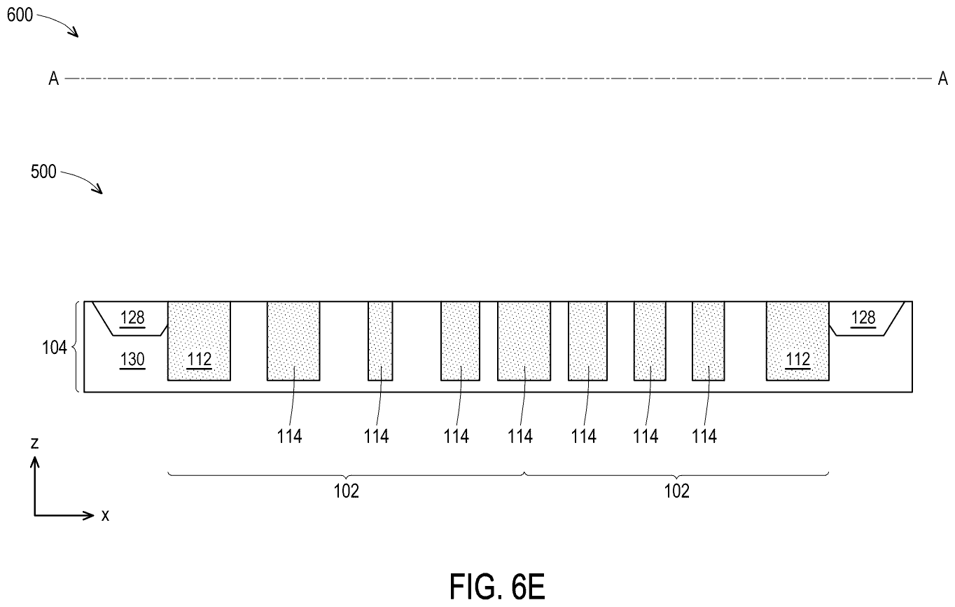

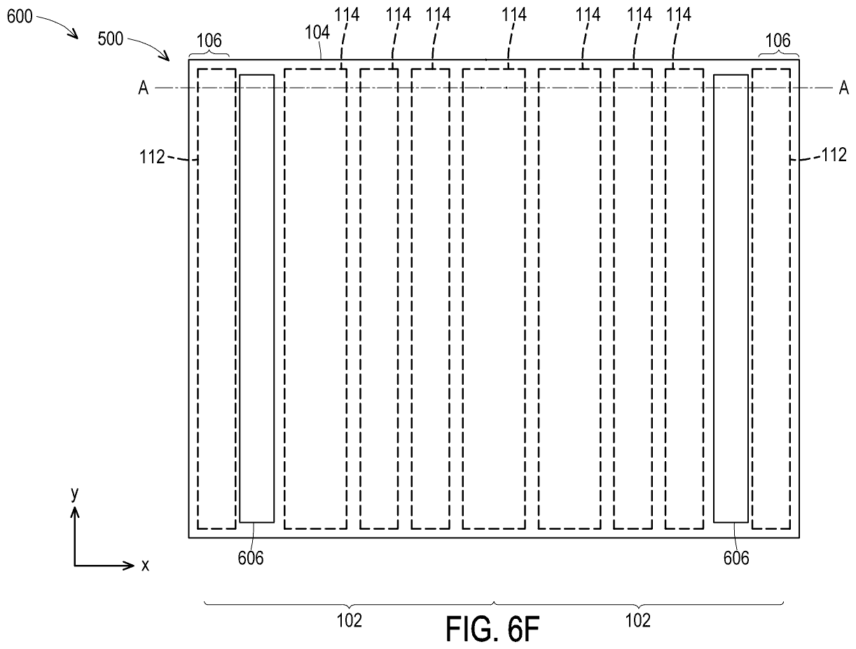

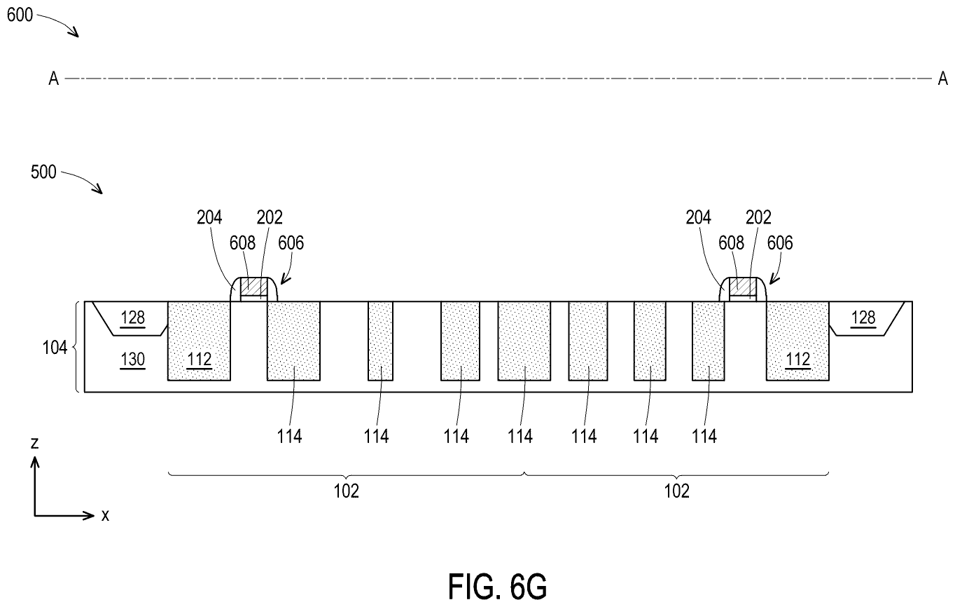

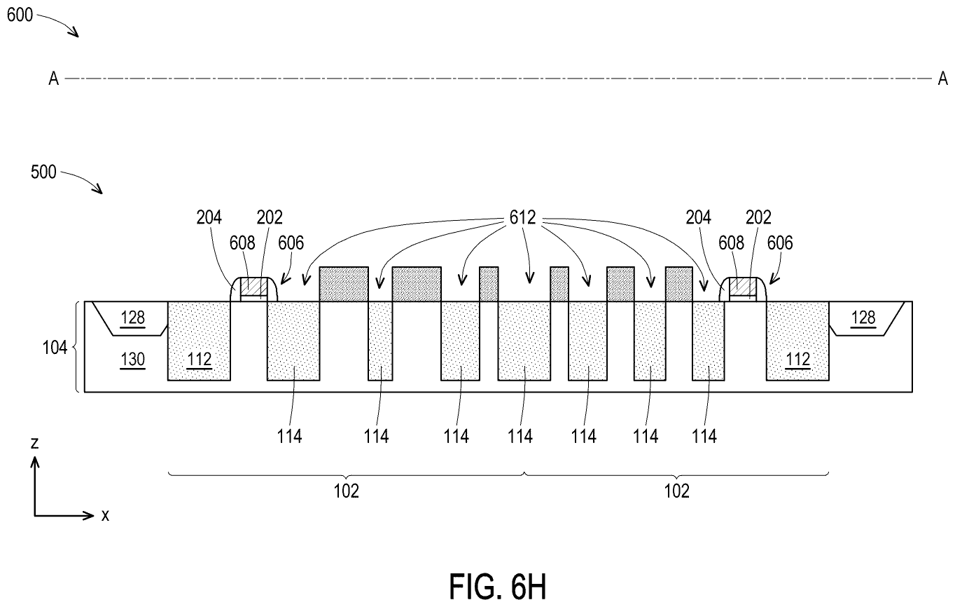

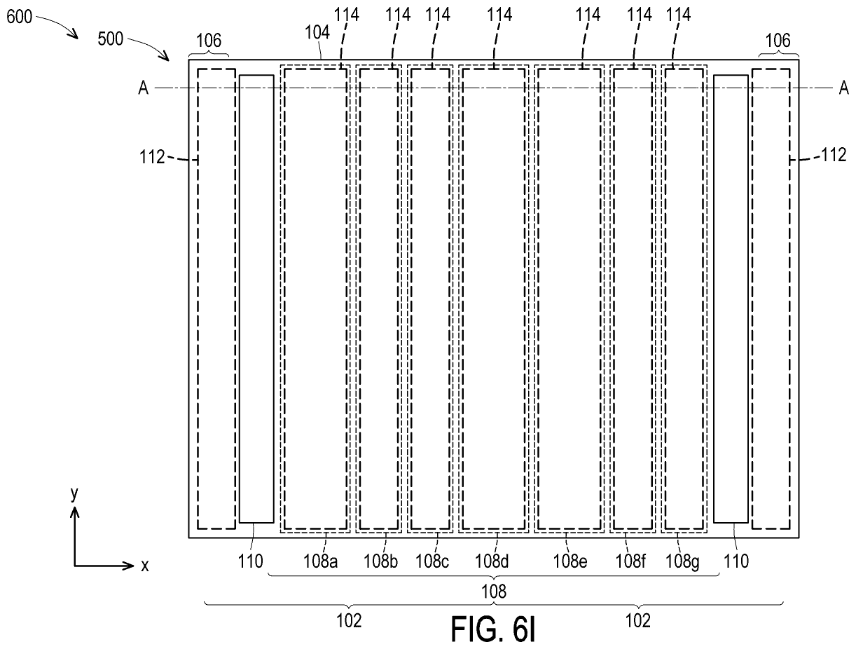

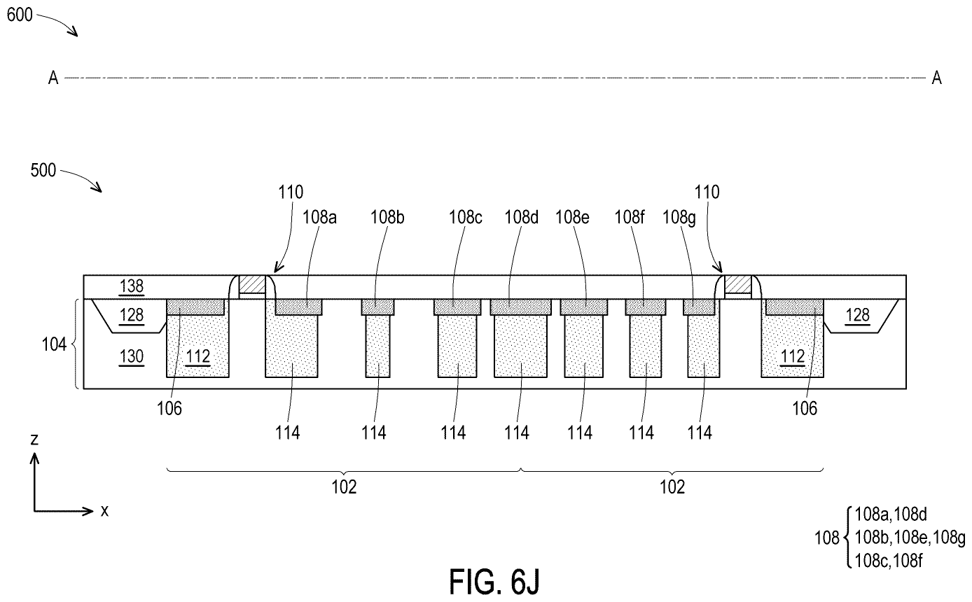

FIGS. 6A-6J are diagrams of an example implementation 600 of ESD protection devices 102 of a semiconductor device 500 described herein. In some implementations, one or more of the operations described in connection with FIGS. 6A-6J may be performed using one or more semiconductor processing tools, such as a deposition tool, an exposure tool, a developer tool, an etch tool, an ion implantation tool, and/or a planarization tool, among other examples.

The operations described in FIGS. 6A-6J are similar to those described in connection with FIGS. 3A-3I. However, operations to form the plurality of non-contiguous (e.g., discontinuous) implant segments 108a, 108b, 108c, 108d, 108e, 108f, and 108g for the semiconductor device 500 differ from processing to form the continuous implant segment of the source/drain region 108 for the semiconductor device 100.

The processing operations shown in FIGS. 6A-6G for semiconductor device 500 are the same as those shown in FIGS. 3A-3G for semiconductor device 100. For example, the implantation mask 602 and corresponding pattern 604 shown in FIG. 6D to form the plurality of non-contiguous lightly doped implant regions 114 is the same as the implantation mask 302 and corresponding pattern 304 shown in FIG. 3D. Also, the arrangement and location of dummy gate structures 606 including sacrificial gate electrodes 608 in FIG. 6G, is the same as the arrangement and location of dummy gate structures 306 including sacrificial gate electrodes 308 in FIG. 3G.

As shown in FIGS. 6H-6I, an implantation mask 610 is formed on the substrate 104, and a pattern 612 is formed in the implantation mask 610. The pattern 612 in the implantation mask is used to selectively further dope the lightly doped implant regions 112 and 114 that are left exposed (e.g., not covered) by the implantation mask 610, to form source/drain regions 106 in the lightly doped implant regions 112 and the non-contiguous implant segments 108a-108g of the source/drain region 108 in the lightly doped implant regions 114. The implantation mask 610 enables the formation of the plurality of non-contiguous implant segments 108a-108g in respective ones of the non-contiguous lightly doped implant regions 114. The plurality of non-contiguous implant segments 108a-108g are spaced apart in the substrate 104 of the semiconductor device 100. Thus, the non-contiguous implant segments 108a-108g are omitted from the regions of the substrate 104 under the portions of the implantation mask 610, resulting in spaces between the non-contiguous implant segments 108a-108g. The spaces between the non-contiguous implant segments 108a-108g correspond to the diffusion regions 134. In some implementations, an ion implantation tool is used to perform one or more ion implantation operations to form the source/drain regions 106 and the non-contiguous implant segments 108a-108g of the source/drain region 108.

The source/drain regions 106 may each be formed in a lightly doped implant region 112, and the non-contiguous (e.g., discontinuous) implant segments 108a-108g of the source/drain region 108 may be formed in the plurality of non-contiguous (e.g., discontinuous) lightly doped implant regions 114. In addition to the implantation mask 610, the dummy gate structures 606 are used as a self-aligned implant mask, so that the exposed regions of the substrate 104, and of the lightly doped implant regions 112 and 114, are selectively doped to form the source/drain regions 106 and the non-contiguous implant segments 108a-108g of the source/drain region 108. This enables well regions in the substrate 104 to be formed under the dummy gate structures 606. In addition, portions of one or more of the lightly doped implant regions 112 and/or 114 may be under part of the dummy gate structures 606 (e.g., under the sidewall spacers 204), so that the overlapped portions of the lightly doped implant regions 112 and/or 114 are masked from ion implantation used to form the source/drain regions 106 and 108.

As shown in FIG. 6J, following ion implantation to form the source/drain regions 106 and the non-contiguous implant segments 108a-108g of the source/drain region 108, an ILD layer 138 is formed on the substrate 104, and a replacement gate process to replace the sacrificial gate electrodes 608 with gate electrodes 206 is performed, thereby forming the gate structures 110. An etch tool may be used to etch the sacrificial gate electrodes 608, and a deposition tool may be used to deposit the gate electrodes 206 in place of the sacrificial gate electrodes 608. A planarization process such as, for example, chemical mechanical planarization (CMP) may be performed following the deposition of the gate electrodes 206 to remove excess metal material from on top of the ILD layer 138.

As indicated above, FIGS. 6A-6J are provided as examples. Other examples may differ from what is described with regard to FIGS. 6A-6J.

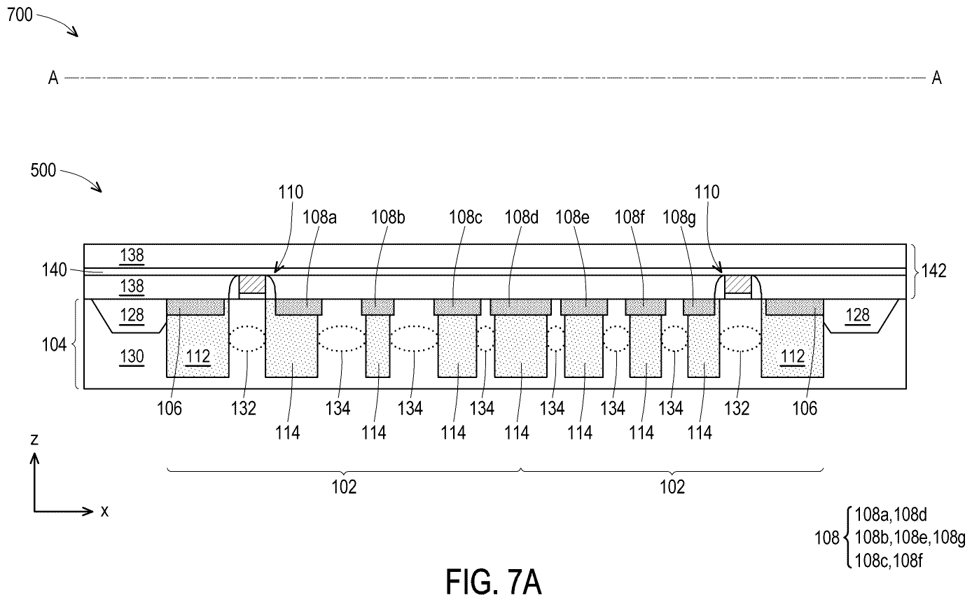

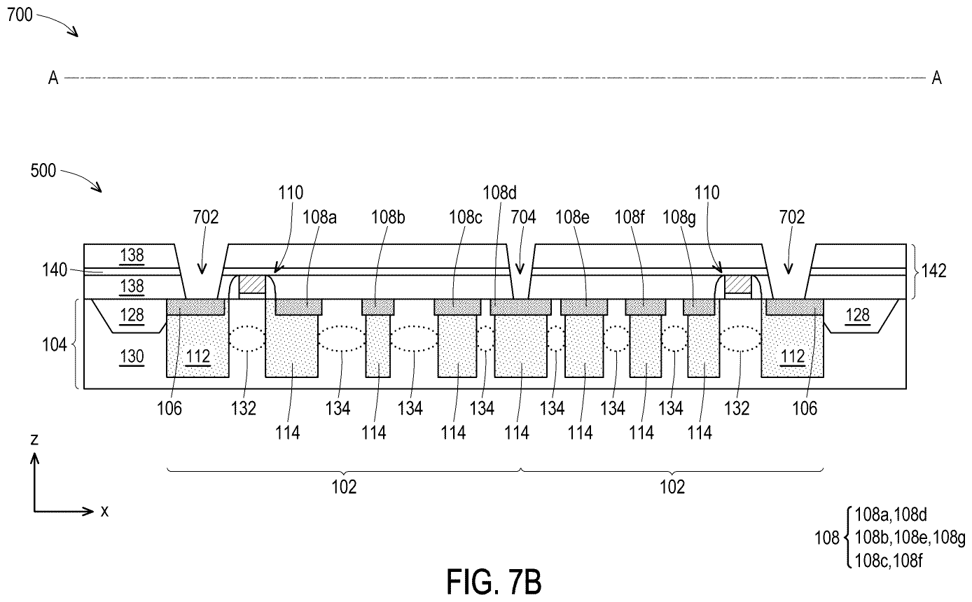

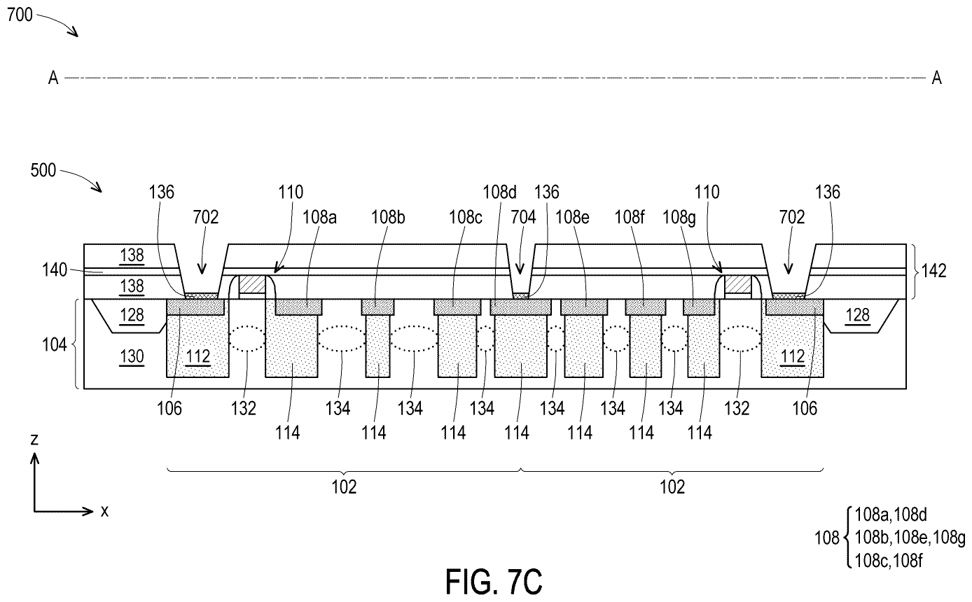

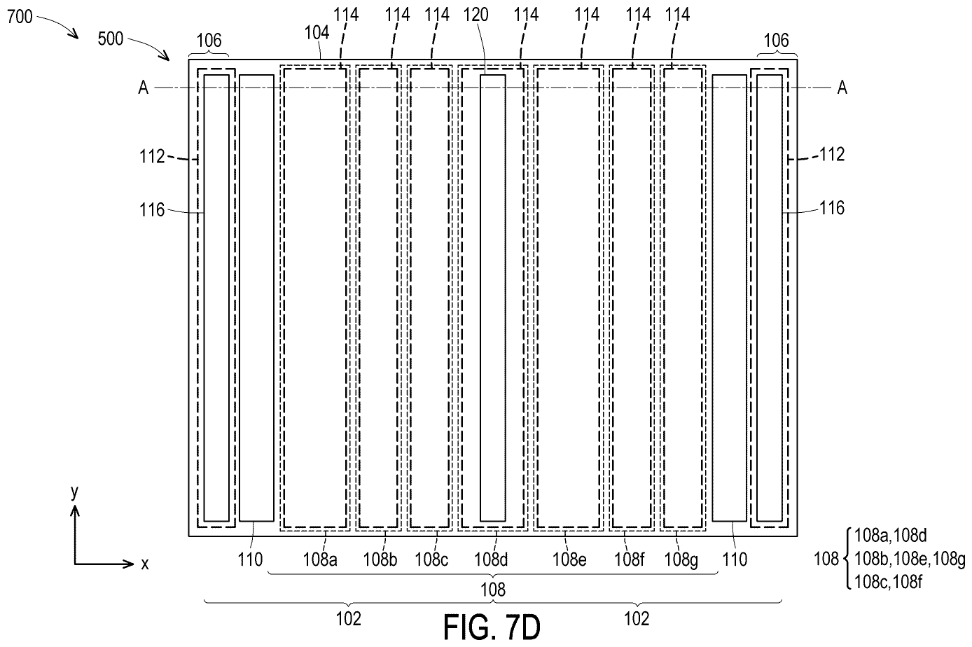

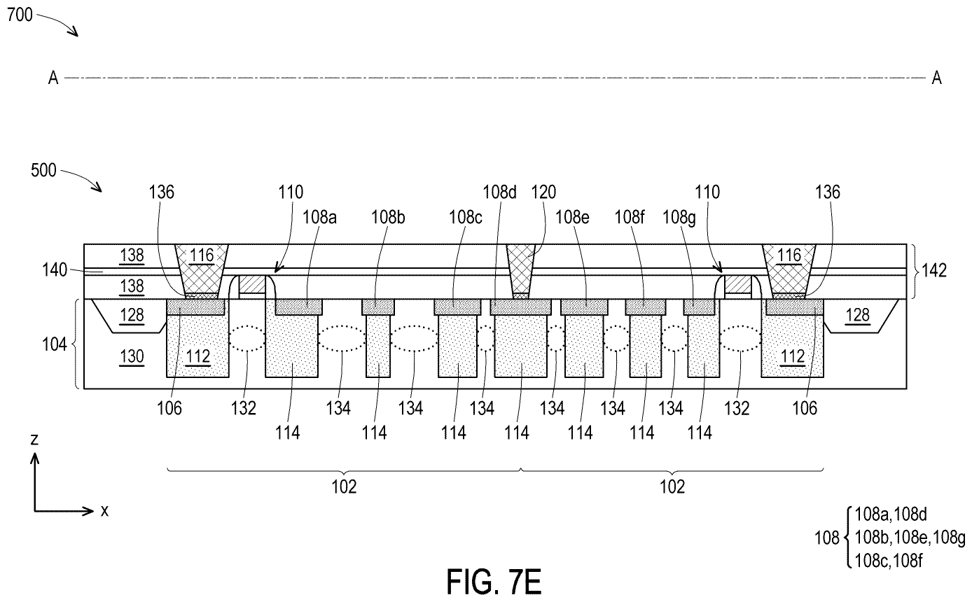

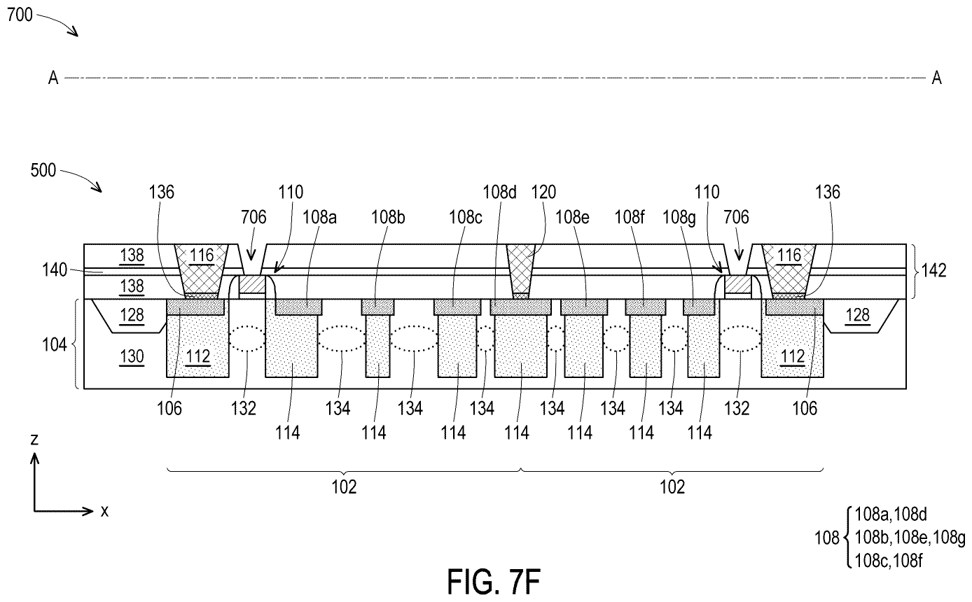

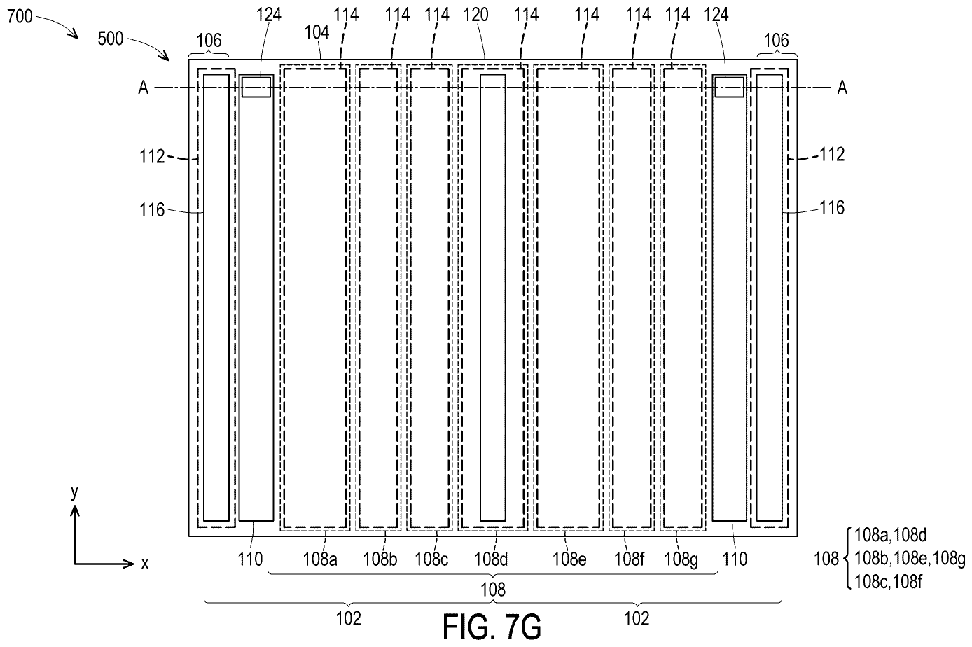

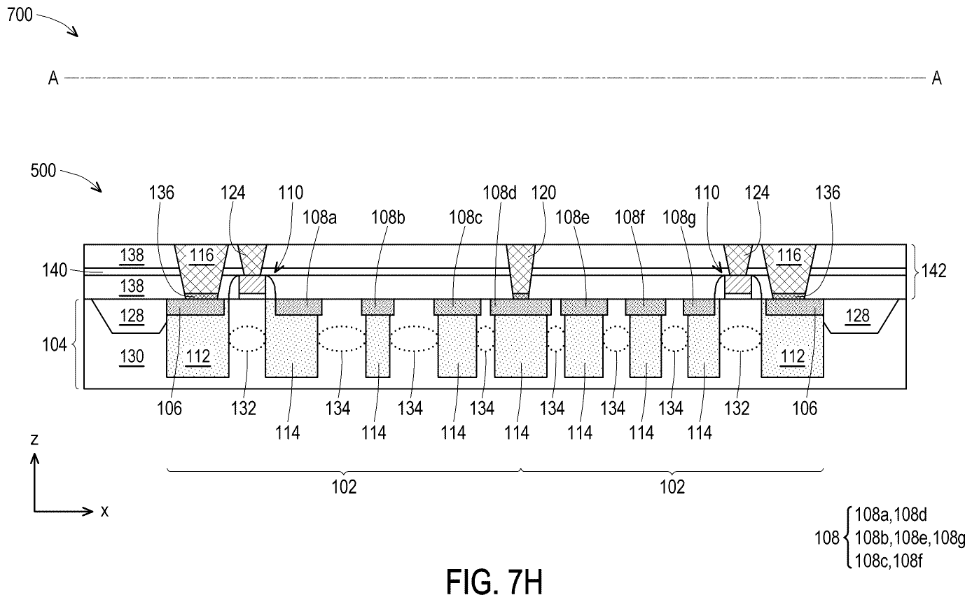

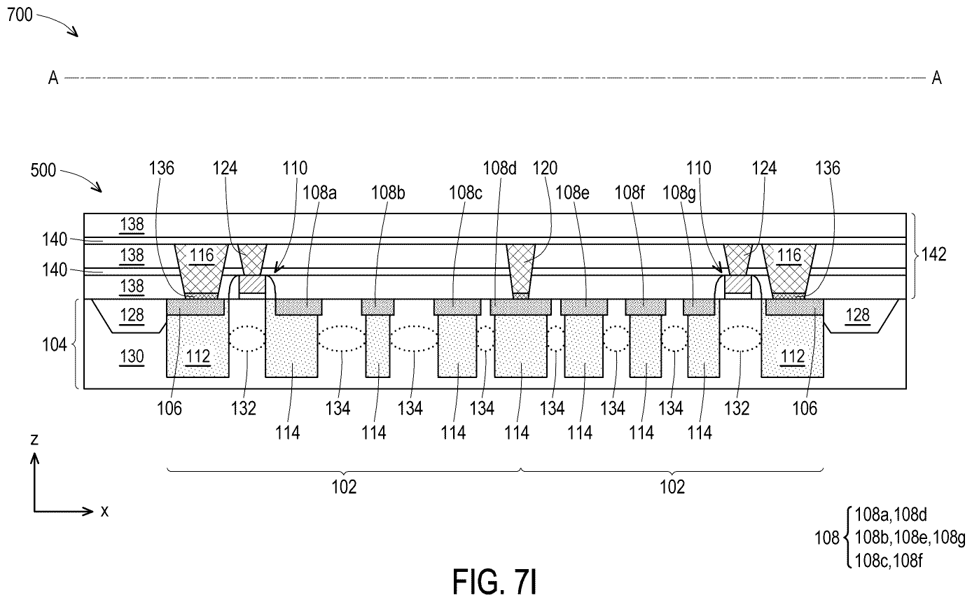

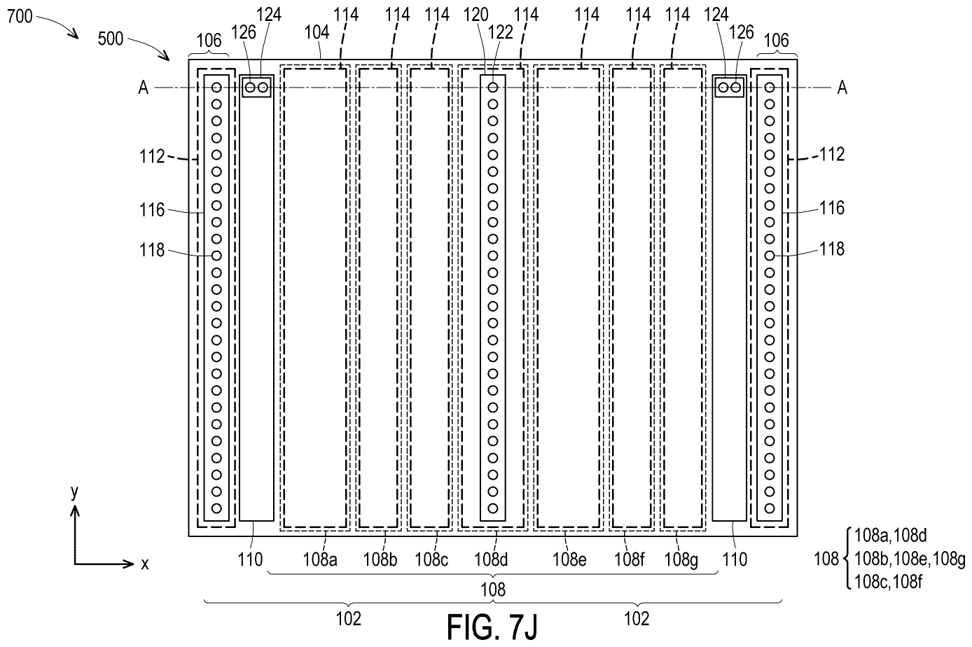

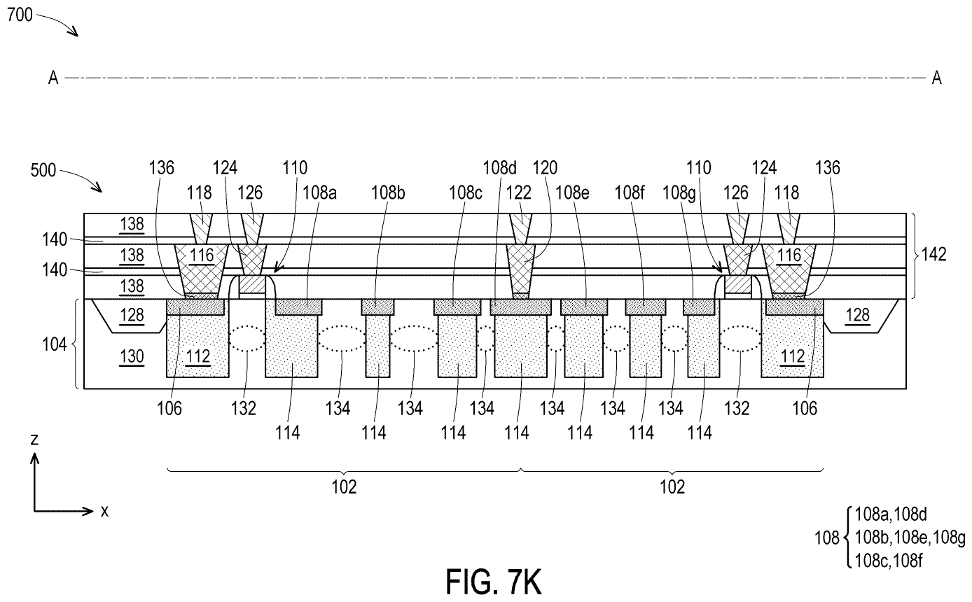

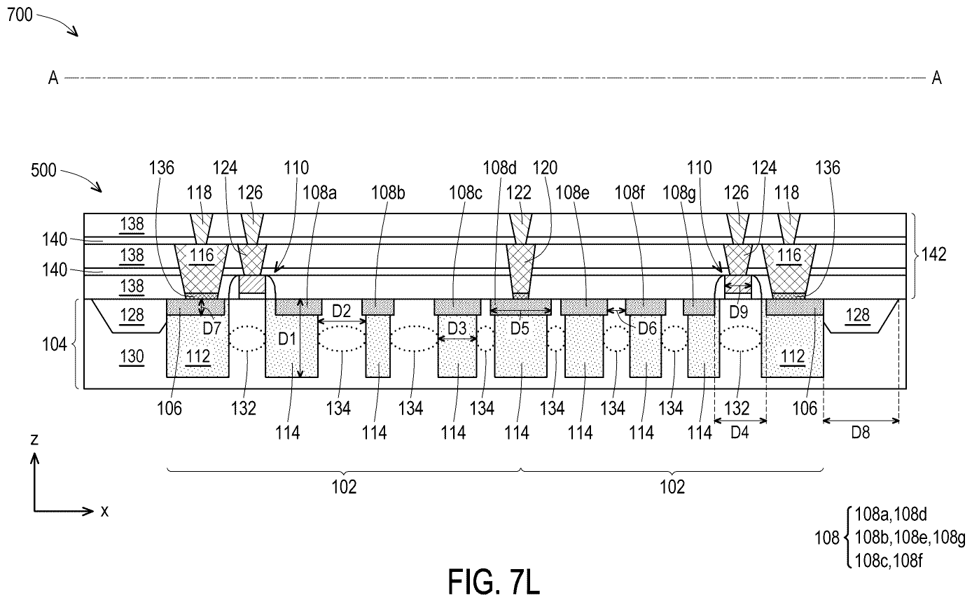

FIGS. 7A-7L are diagrams of an example implementation 700 of forming an interconnect layer 142 of a semiconductor device 500 described herein. In some implementations, one or more of the semiconductor processing operations described in connection with FIGS. 7A-7L may be performed after one or more operations described in connection with FIGS. 6A-6J. In some implementations, one or more of the operations described in connection with FIGS. 7A-7L may be performed using one or more semiconductor processing tools, such as a deposition tool, an exposure tool, a developer tool, an etch tool, and/or a planarization tool, among other examples.

The operations described in FIGS. 7A-7K are the same as or similar to those described in connection with FIGS. 4A-4K. However, there are some differences in connection with source/drain contact(s) 120 formed on one or more of the plurality of non-contiguous (e.g., discontinuous) implant segments 108a, 108b, 108c, 108d, 108e, 108f, and 108g for the semiconductor device 500 in comparison to a source/drain contact 120 formed on the continuous implant segment of the source/drain region 108 for the semiconductor device 100.

As shown in FIG. 7A, similar to what is shown in FIG. 4A, one or more ILD layers 138 and one or more ESLs 140 of the interconnect layer 142 may be formed above the substrate 104 and over the gate structures 110 of the ESD protection devices 102. As shown in FIG. 7B, recesses 702 and 704 may be formed through the ILD layer(s) 138 and the ESL(s) 140. Similar to the recess 402, the recesses 702 may be formed over the source/drain regions 106 of the ESD protection devices 102. The recess 704 may be formed over an implant segment 108d of the source/drain region 108. In particular, the recess 704 may be formed over the implant segment 108d of the source/drain region 108 that is located farthest away from both of the gate structures 110. Alternatively, the recess 704 may be formed over another implant segment of the source/drain region 108. In some implementations, recesses may be formed over more than one implant segment of the source/drain region, so that more than one source/drain contact 120 can be formed.

In some implementations, a pattern in a photoresist layer is used to etch the ILD layer(s) 138 and the ESL(s) 140 to form the recesses 702 and 704. In these implementations, a deposition tool may be used to form the photoresist layer on the topmost ILD layer 138. An exposure tool may be used to expose the photoresist layer to a radiation source to pattern the photoresist layer. A developer tool may be used to develop and remove portions of the photoresist layer to expose the pattern. An etch tool may be used to etch the ILD layer(s) 138 and the ESL(s) 140 based on the pattern to form the recesses 702 and 704. In some implementations, the etch operation includes a dry etch operation (e.g., a plasma-based etch operation, a gas-based etch operation), a wet chemical etch operation, and/or another type of etch operation. In some implementations, a photoresist removal tool may be used to remove the remaining portions of the photoresist layer (e.g., using a chemical stripper, plasma ashing, and/or another technique). In some implementations, a hard mask layer is used as an alternative technique for forming the recesses 702 and 704 based on a pattern.

The subsequent processing operations shown in FIGS. 7C-7K for semiconductor device 500 are the same as or similar to those shown in FIGS. 4C-4K for semiconductor device 100. For example, the salicide process (e.g., a self-aligned silicide process) to form silicide layers 136 on the tops of the source/drain regions 106 at the bottoms of the recesses 702, and to form a silicide layer 136 on the top of the implant segment 108d of the source/drain region 108 at the bottoms of the recess 704 may be the same as that described in connection with FIG. 4C.

As shown in FIGS. 7D and 7E, the source/drain contacts 116 are formed on the silicide layers 136 in the recesses 702 such that the source/drain contacts 116 are located above the source/drain regions 106. The source/drain contact 120 is formed on the silicide layer 136 in the recess 704 such that the source/drain contact 120 is located above an implant segment (e.g., the implant segment 108d) of the source/drain region 108. One or more additional source/drain contacts 120 may be similarly formed on different implant segments of the source/drain region 108.

As shown in FIG. 7F, recesses 706, which are the same as or similar to the recesses 406, may be formed through the ILD layer(s) 138 and the ESL(s) 140. The recesses 706 may be formed over the gate structures 110 of the ESD protection devices 102. In some implementations, a pattern in a photoresist layer is used to etch the ILD layer(s) 138 and the ESL(s) 140 to form the recesses 706. In these implementations, a deposition tool may be used to form the photoresist layer on the topmost ILD layer 138. An exposure tool may be used to expose the photoresist layer to a radiation source to pattern the photoresist layer. A developer tool may be used to develop and remove portions of the photoresist layer to expose the pattern. An etch tool may be used to etch the ILD layer(s) 138 and the ESL(s) 140 based on the pattern to form the recesses 706. In some implementations, the etch operation includes a dry etch operation (e.g., a plasma-based etch operation, a gas-based etch operation), a wet chemical etch operation, and/or another type of etch operation. In some implementations, a photoresist removal tool may be used to remove the remaining portions of the photoresist layer (e.g., using a chemical stripper, plasma ashing, and/or another technique). In some implementations, a hard mask layer is used as an alternative technique for forming the recesses 706 based on a pattern.

The remaining processes to form the gate contacts 124 in the recesses 706, the source/drain interconnects 118, the source/drain interconnects 122, and the gate interconnects 126 shown in FIGS. 7G-7K are the same as or similar to those shown in FIGS. 4G-4K.

FIG. 7L illustrates dimensions D1-D9 of different portions of the semiconductor device 500, which may also be applicable to the same or similar portions of the semiconductor device 100. As shown in FIG. 7L, the dimension D1 refers to a depth in the z-direction of a lightly doped implant region 114, which may be included in the range of approximately 1000 angstroms to approximately 2000 angstroms. However, other values and ranges are within the scope of the present disclosure. The dimension D1 may also apply to a depth in the z-direction of a lightly doped implant region 112. The dimension D2 refers to a width in the x-direction of a space between two adjacent lightly doped implant regions 114, which may be included in the range of approximately 0.1 micrometers to approximately 0.5 micrometers. However, other values and ranges are within the scope of the present disclosure. In some implementations, if the dimension D2 is greater than 0.5 micrometers, the on-resistance (Rₒₙ) of an ESD protection device 102 may be too high, resulting in an inability of the ESD protection device 102 to protect other functional devices or circuits from ESD. If the dimension D2 is less than 0.1 micrometers, the effective dopant concentration in the adjacent lightly doped implant regions 114 may be too high, resulting in high surface electric fields, and low ESD performance (e.g., HBM=0V).

The dimension D3 refers to a width in the x-direction of a lightly doped implant region 114, which may be included in the range of approximately 0.1 micrometers to approximately 0.5 micrometers. However, other values and ranges are within the scope of the present disclosure. The dimension D3 may also apply to a width in the x-direction of a lightly doped implant region 112. The dimension D4 refers to a distance in the x-direction between an edge of a lightly doped implant region 112 and an edge of an implant segment of a source/drain region 106 in the lightly doped implant region 112, or a distance in the x-direction between an edge of a lightly doped implant region 114 and an edge of an implant segment of a source/drain region 108 in the lightly doped implant region 114. The dimension D4 may be included in the range of approximately 0.005 micrometers to approximately 0.3 micrometers. However, other values and ranges are within the scope of the present disclosure. In some implementations, the edges of lightly doped implant regions 112 or 114 are not spaced apart from and are flush with or overlap edges of implant segments of the source/drain regions 106 or 108. The dimension D5 refers to a width in the x-direction of an implant segment (e.g. implant segment 108d) of the source/drain region 108, which may be included in the range of approximately 0.1 micrometers to approximately 0.5 micrometers. However, other values and ranges are within the scope of the present disclosure.

The dimension D5 may also apply to a width in the x-direction of an implant segment of the source/drain region 106. The dimension D6 refers to a width in the x-direction of a space between two adjacent implant segments (e.g., implant segments 108e and 108f) of the source/drain region 108, which may be included in the range of approximately 0.1 micrometers to approximately 0.5 micrometers. However, other values and ranges are within the scope of the present disclosure. The dimension D7 refers to a thickness in the z-direction of an implant segment of the source/drain region 106, which may be included in the range of approximately 1000 angstroms to approximately 2000 angstroms. However, other values and ranges are within the scope of the present disclosure. The dimension D7 may also apply to a thickness in the z-direction of an implant segment of the source/drain region 108. The dimension D8 refers to a length (Lg) in the x-direction of a gate electrode, which may be included in the range of approximately 10 nanometers to approximately 1000 nanometers. However, other values and ranges are within the scope of the present disclosure. The dimension D9 refers to a width in the x-direction of an STI region 128, which may be included in the range of approximately 0.1 micrometers to approximately 10 micrometers. However, other values and ranges are within the scope of the present disclosure.

As indicated above, FIGS. 7A-7L are provided as examples. Other examples may differ from what is described with regard to FIGS. 7A-7L.

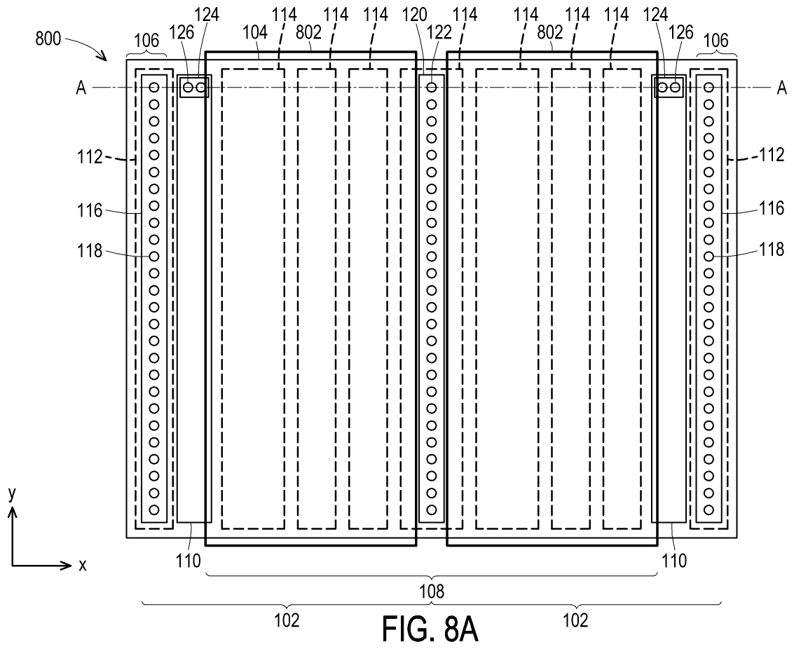

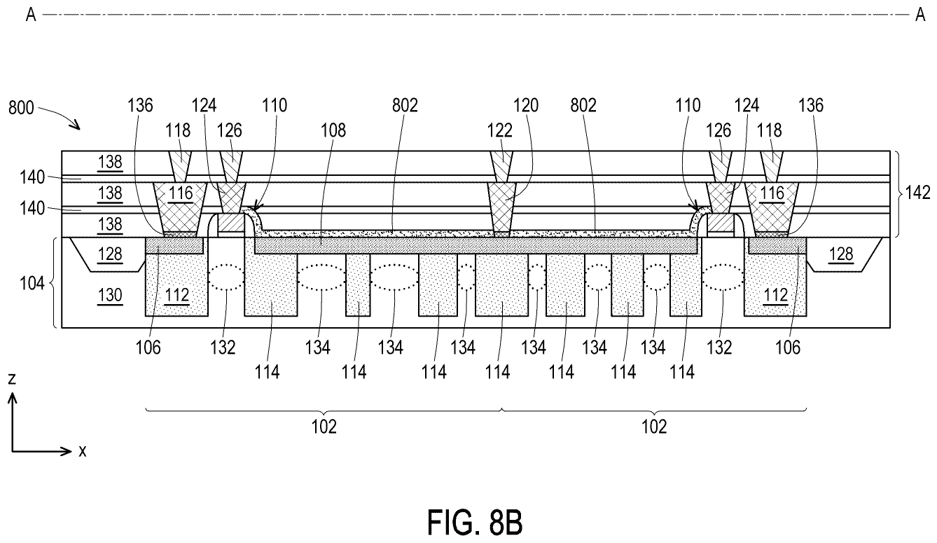

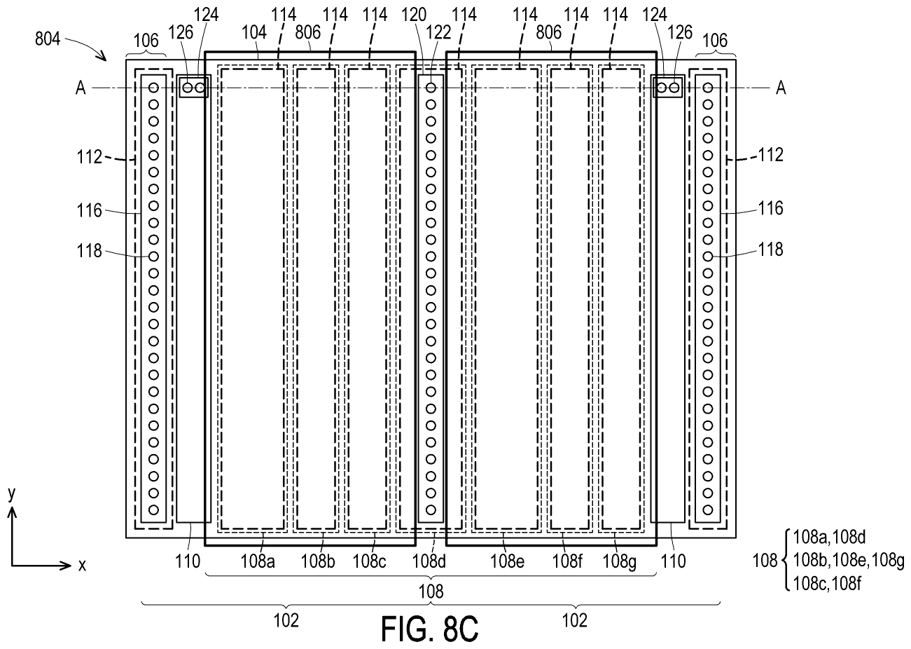

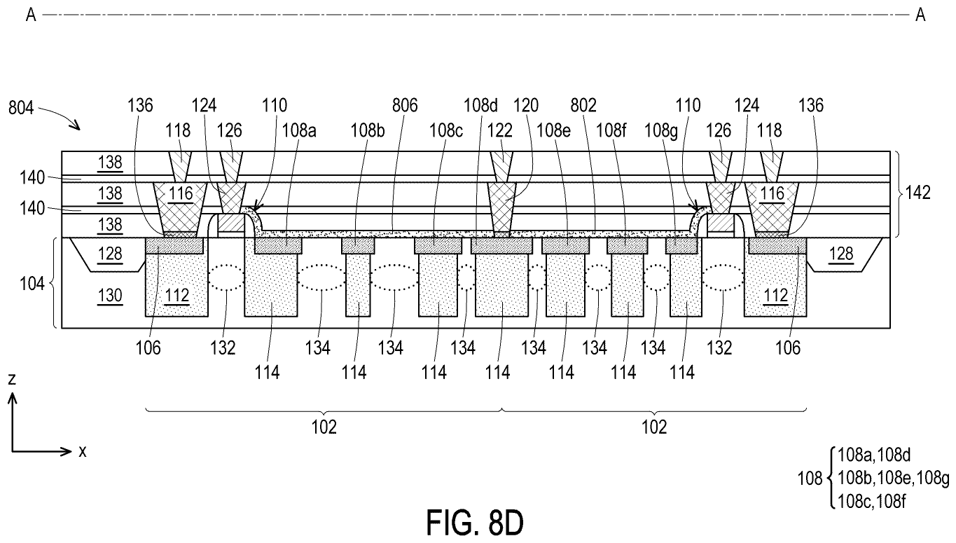

FIGS. 8A and 8B are diagrams of an example semiconductor device 800 described herein, and FIGS. 8C and 8D are diagrams of an example semiconductor device 804 described herein. FIGS. 8A and 8C illustrate top views of the semiconductor devices 800 and 804, respectively. FIGS. 8B and 8D illustrate cross-section views of the semiconductor devices 800 and 804 along the lines A-A in FIGS. 8A and 8C, respectively. As shown in FIGS. 8A and 8B, the semiconductor device 800 includes a similar combination and arrangement of layers and/or structures as the semiconductor device 100 illustrated and described in connection with FIGS. 1A and 1B. However, as shown in FIGS. 8A and 8B, the ESD protection devices 102 of the semiconductor device 800 further includes a resist protective oxide (RPO) layer 802 over the continuous implant segment of the source/drain region 108 and over sides of the gate structures 110 facing the source/drain region 108.

As shown in FIGS. 8C and 8D, the semiconductor device 804 includes a similar combination and arrangement of layers and/or structures as the semiconductor device 500 illustrated and described in connection with FIGS. 5A and 5B. However, as shown in FIGS. 8C and 8D, the ESD protection devices 102 of the semiconductor device 804 further include a resist protective oxide (RPO) layer 806 over the implant segments 108a-108g of the source/drain region 108 and over sides of the gate structures 110 facing the source/drain region 108. The RPO layers 802 and 806 may include an oxide material such as a silicon oxide (SiOₓ such as SiO₂) and/or another dielectric oxide material.

The RPO layers 802 and 806 may be included in an ESD protection device 102 for reduced surface field (RESURF) tuning. The RPO layers 802 and 806 reduce the electric field at the surface of the substrate 104 between the gate structures 110 and the source/drain contact 120, which enables a lower peak electric field strength to be achieved than without the RPO layers 802 and 806. The lower peak electric field strength enables the ESD protection devices 102 to handle higher voltages (e.g., stronger ESD events) without experiencing breakdown. Alternatively, the RPO layers 802 and 806 may be omitted, as in the semiconductor devices 100 and 500, to achieve higher on current (Iₒₙ) for the ESD protection devices 102.

The RPO layers 802 and 806 may be formed after formation of the source/drain regions 106 and 108, as described in connection with FIGS. 3G-3I and FIGS. 6H-6J. For example, the RPO layers 802 and 806 may be deposited over the semiconductor devices 800 and 804, including over the source/drain regions 106 and 108, and over the gate structures 110. A patterned masking layer may be formed on the RPO layers 802 and 806 and used to etch the RPO layers 802 and 806 to remove portions of the RPO layers 802 and 806. The remaining portions of the RPO layers 802 and 806 may be included over sides of the gate structures 110 facing the source/drain region 108, and on the source/drain region 108.

As indicated above, FIGS. 8A-8D are provided as examples. Other examples may differ from what is described with regard to FIGS. 8A-8D.

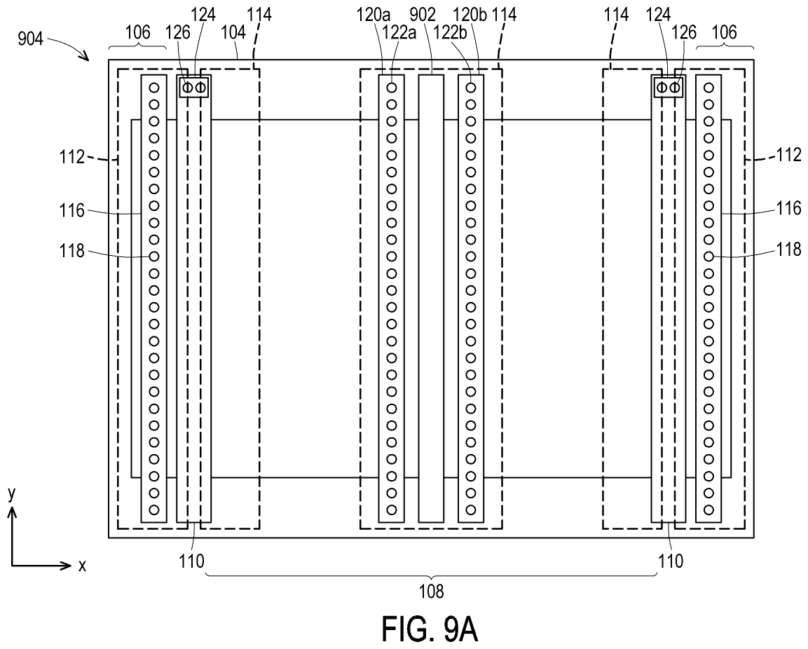

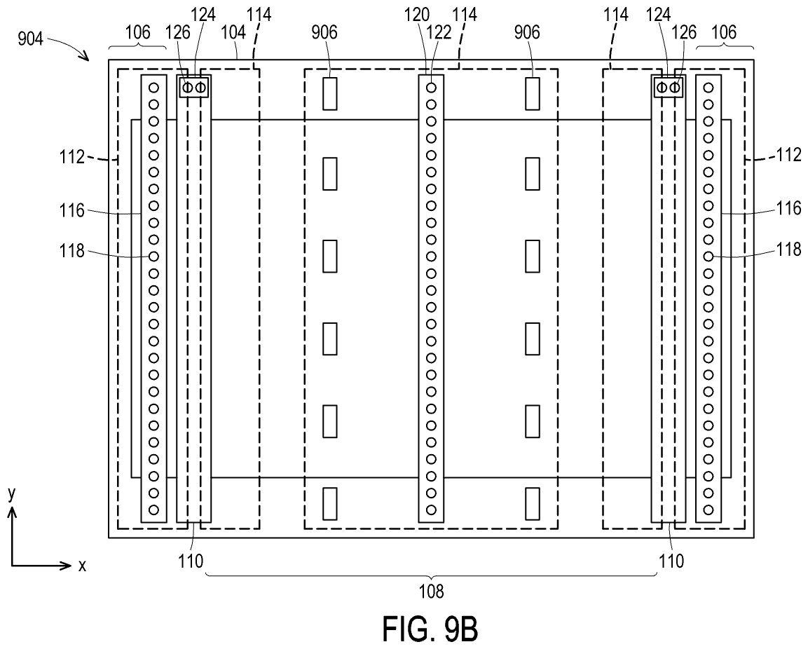

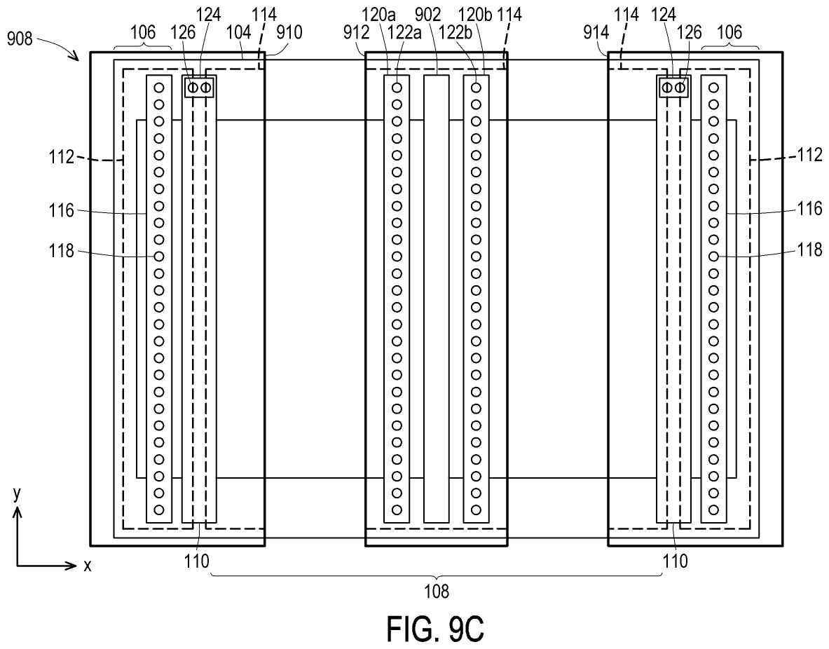

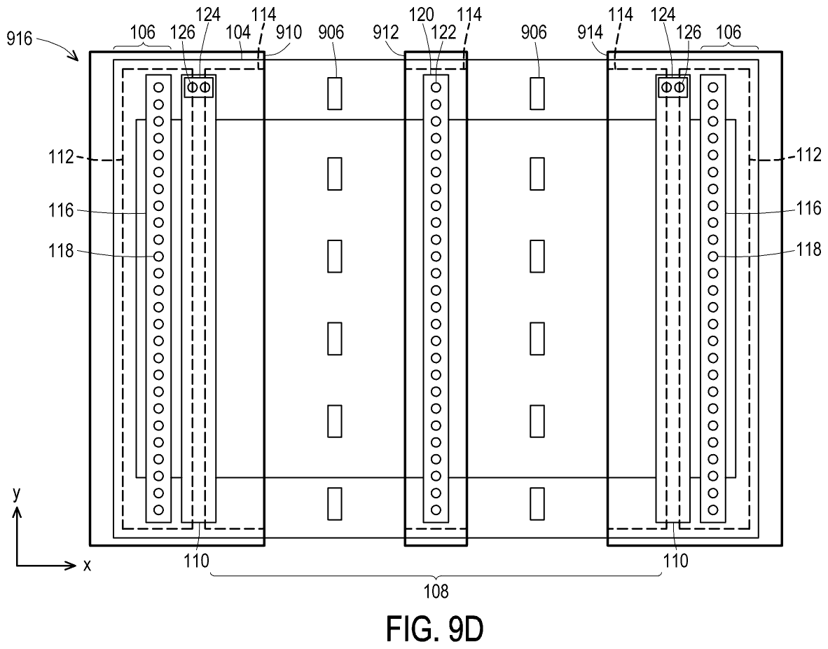

FIGS. 9A-9D are top view diagrams of example semiconductor devices 900, 904, 908, and 916 described herein. As shown in FIG. 9A, the semiconductor device 900 includes a similar combination and arrangement of layers and/or structures as the semiconductor device 100 illustrated and described in connection with FIGS. 1A and 1B. However, as shown in FIG. 9A, the semiconductor device 900 includes a dummy gate structure 902 at a central portion of the source/drain region 108, and two source/drain contacts 120a and 120b and corresponding interconnects 122a and 122b on opposite sides of the dummy gate structure 902.

A dummy gate structure 902 is a non-active gate structure that is non-operational in the semiconductor device 900, and in some implementations is not connected to back-end circuitry in the semiconductor device 900. The dummy gate structure 902 is a “gate structure” in that the dummy gate structure 902 is formed during the same processes as the gate structures 110 of the ESD protection devices 102. The dummy gate structure 902 extends in the y-direction and approximately parallel to the gate structures 110.

As shown in FIG. 9B, the semiconductor device 904 includes a similar combination and arrangement of layers and/or structures as the semiconductor device 100 illustrated and described in connection with FIGS. 1A and 1B. However, as shown in FIG. 9B, the semiconductor device 904 includes a plurality of discontinuous dummy gate segments 906. The discontinuous dummy gate segments 906 may be spaced apart and arranged in the y-direction in the semiconductor device 904.

Including discontinuous dummy gate segments 906, as opposed to a continuous structure that extends in the y-direction, may enable an increased pattern density to be achieved for the masking layer that is used to etch the layers of the dummy gate segments 906. The increased pattern density increases the amount of radiation that passes through the masking layer during a photolithography operation to pattern the masking layer, resulting in increased exposure efficiency and, therefore, increased luminous flux. The increased luminous flux decreases the likelihood of underdevelopment of the pattern in the masking layer, which decreases the likelihood of residual masking material (sometimes referred to as photoresist scum) remaining in the masking layer. The reduced likelihood of residual masking material reduces the likelihood that under-etching might otherwise occur because of the residual material blocking an etchant that is used during etching of the layers of the gate structures 110. Therefore, the inclusion of the discontinuous dummy gate segments 906 reduces the likelihood of defect formation in the gate structures 110.

As shown in FIG. 9C, the semiconductor device 908 includes a similar combination and arrangement of layers and/or structures as the semiconductor device 500 illustrated and described in connection with FIGS. 5A and 5B. However, as shown in FIG. 9C, similar to the semiconductor device 900, the semiconductor device 908 includes a dummy gate structure 902 at a central portion of the source/drain region 108, and two source/drain contacts 120a and 120b and corresponding interconnects 122a and 122b on opposite sides of the dummy gate structure 902. FIG. 9C further illustrates the segmentation of the source/drain regions 106 and 108, by illustrating implant segments 910, 912 and 914. The implant segments 910 and 914 may be implant segments of the source/drain region 106, and the implant segment 912 may be an implant segment of the source/drain region 108.

As shown in FIG. 9D, the semiconductor device 916 includes a similar combination and arrangement of layers and/or structures as the semiconductor device 500 illustrated and described in connection with FIGS. 5A and 5B. However, as shown in FIG. 9D, similar to the semiconductor device 904, the semiconductor device 916 includes the plurality of discontinuous dummy gate segments 906 spaced apart and arranged in the y-direction in the semiconductor device 916. Like the semiconductor device 908, the semiconductor device 916 may include implant segments 910 and 914 of the source/drain region 106, and the implant segment 912 of the source/drain region 108.

As indicated above, FIGS. 9A-9D are provided as examples. Other examples may differ from what is described with regard to FIGS. 9A-9D.

FIG. 10 is a diagram of an example semiconductor device 1000 described herein. The semiconductor device 1000 includes an example of a semiconductor die, an IC chip, or another type of semiconductor device 1000 that includes a core circuitry region 1002, I/O devices 1004, and one or more ESD protection devices 1006 and/or 1008 included in the signal path between the I/O devices 1004 and the core circuitry region 1002. The core circuitry region 1002 includes the logic circuits, the memory circuits, and/or other functional circuits of the semiconductor device 1000. The I/O devices 1004 may include contact pads, I/O fanout structures, and/or another type of I/O devices.

The ESD protection devices 1006 and 1008 may each be implemented by one or more example implementations of semiconductor devices 100, 500, 800, 804, 900, 904, 908, and/or 916 described herein. In some implementations, the ESD protection devices 1006 include ggNMOS protection devices and the ESD protection devices 1008 include gdPMOS protection devices. In some implementations, the ESD protection devices 1008 include ggNMOS protection devices and the ESD protection devices 1006 include gdPMOS protection devices. The ESD protection devices 1006 and 1008 are configured to provide ESD protection for the core circuitry region 1002 for the signals transferred between the I/O devices 1004 and the core circuitry region 1002.

As indicated above, FIG. 10 is provided as an example. Other examples may differ from what is described with regard to FIG. 10.

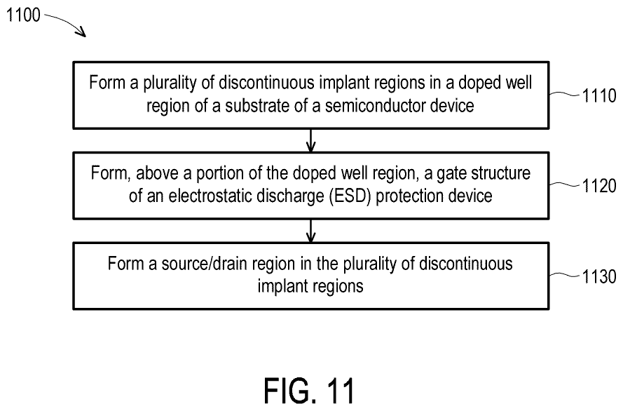

FIG. 11 is a flowchart of an example process 1100 associated with forming a semiconductor device. In some implementations, one or more process blocks of FIG. 11 are performed using one or more semiconductor processing tools, such as a deposition tool, an exposure tool, a developer tool, an etch tool, a planarization tool, an ion implantation tool, an annealing tool, a wafer/die transport tool, and/or another type of semiconductor processing tool.

As shown in FIG. 11, process 1100 may include forming a plurality of discontinuous implant regions in a doped well region of a substrate of a semiconductor device (block 1110). For example, one or more semiconductor processing tools may be used to form a plurality of discontinuous implant regions (e.g., lightly doped implant regions 114) in a doped well region (e.g., well region 130) of a substrate (e.g., substrate 104) of a semiconductor device (e.g., semiconductor device 100, 500, 800, 804, 900, 904, 908, 916), as described herein. In some implementations, portions of the doped well region are located laterally between adjacent implant regions of the plurality of discontinuous implant regions.

As further shown in FIG. 11, process 1100 may include forming, above a portion of the doped well region, a gate structure of an electrostatic discharge (ESD) protection device (block 1120). For example, one or more semiconductor processing tools may be used to form, above a portion of the doped well region, a gate structure (e.g., gate structure 110) of an ESD protection device (e.g., ESD protection device 102), as described herein.

As further shown in FIG. 11, process 1100 may include forming a source/drain region in the plurality of discontinuous implant regions (block 1130). For example, one or more semiconductor processing tools may be used to form a source/drain region (e.g., source/drain region 108) in the plurality of discontinuous implant regions, as described herein. In some implementations, the source/drain region is adjacent to a side of the gate structure.

Process 1100 may include additional implementations, such as any single implementation or any combination of implementations described below and/or in connection with one or more other processes described elsewhere herein.

In a first implementation, forming the plurality of discontinuous implant regions includes forming a mask (e.g., implantation mask 302, 602) on the portions of the doped well region, and performing an ion implantation process on other portions of the doped well region left exposed by the mask to form the plurality of discontinuous implant regions in the other portions of the doped well region.

In a second implementation, alone or in combination with the first implementation, forming the source/drain region in the plurality of discontinuous implant regions includes performing an ion implantation process on the plurality of discontinuous implant regions and on the portions of the doped well region between the adjacent implant regions of the plurality of discontinuous implant regions to form a continuous source/drain segment in the plurality of discontinuous implant regions and in the portions of the doped well region.

In a third implementation, alone or in combination with one or more of the first and second implementations, process 1100 includes depositing one or more dielectric layers (e.g., ILD layer(s) 138, ESL(s) 140) on the substrate over the continuous source/drain segment and over the gate structure, etching the one or more dielectric layers to form a recess (e.g., recess 404) exposing a surface of the continuous source/drain segment, and depositing conductive material in the recess to form a contact (e.g., source/drain contact 120) on the surface of the continuous source/drain segment.

In a fourth implementation, alone or in combination with one or more of the first through third implementations, forming the source/drain region in the plurality of discontinuous implant regions includes forming a mask (e.g., implantation mask 610) on the portions of the doped well region, and performing an ion implantation process on exposed portions of the plurality of discontinuous implant regions left exposed by the mask to form a plurality of discontinuous source/drain segments (e.g., implant segments 108a-108g) in the plurality of discontinuous implant regions.

In a fifth implementation, alone or in combination with one or more of the first through fourth implementations, process 1100 includes depositing one or more dielectric layers (e.g., ILD layer(s) 138, ESL(s) 140) on the substrate over the plurality of discontinuous source/drain segments and over the gate structure, etching the one or more dielectric layers to form a recess (e.g., recess 704) exposing a surface of a source/drain segment of the plurality of discontinuous source/drain segments, and depositing conductive material in the recess to form a contact (e.g., source/drain contact 120) on the surface of the source/drain segment.

Although FIG. 11 shows example blocks of process 1100, in some implementations, process 1100 includes additional blocks, fewer blocks, different blocks, or differently arranged blocks than those depicted in FIG. 11. Additionally, or alternatively, two or more of the blocks of process 1100 may be performed in parallel.

In this way, a semiconductor device includes an ESD protection device that includes a plurality of non-contiguous implant portions that are spaced apart with respective well regions between the non-contiguous implant portions in a substrate of the semiconductor device. The space between the non-contiguous implant portions provides areas in the substrate in which dopants from the non-contiguous implant portions may diffuse. Thus, the dopants, which may have been added during, for example, manufacturing operations for the semiconductor device, diffuse into the substrate across a greater area of the substrate than in a source/drain region including continuous implant portions. As a result, the dopant concentration from the implant portions may be reduced in the substrate. This reduces the build-up and concentration of dopants near a gate structure, which reduces the strength of the electric field near the gate structure. The reduced strength of the electric field near the gate structure lessens the damage caused to the ESD protection device across multiple ESD events, thereby increasing the operational life of the ESD protection device.

As described in greater detail above, some implementations described herein provide a semiconductor device. The semiconductor device includes a substrate including a doped well region including a first dopant type. The semiconductor device includes an ESD protection device in the substrate. The ESD protection device includes a plurality of discontinuous implant regions in the doped well region, and including a second dopant type, where the plurality of discontinuous implant regions are arranged in a lateral direction in the semiconductor device. The ESD protection device further includes a gate structure above the substrate and adjacent to an edge of an implant region of the plurality of discontinuous implant regions, a first source/drain region adjacent to a first side of the gate structure, and a second source/drain region adjacent to a second side of the gate structure opposing the first side, where the second source/drain region includes the second dopant type.

As described in greater detail above, some implementations described herein provide a method. The method includes forming a plurality of discontinuous implant regions in a doped well region of a substrate of a semiconductor device, where portions of the doped well region are located laterally between adjacent implant regions of the plurality of discontinuous implant regions. The method includes forming, above a portion of the doped well region, a gate structure of an ESD protection device. The method includes forming a source/drain region in the plurality of discontinuous implant regions, where the source/drain region is adjacent to a side of the gate structure.

As described in greater detail above, some implementations described herein provide a semiconductor device. The semiconductor device includes a substrate including a doped well region. The semiconductor device includes a first gate structure and a second gate structure on the substrate, where the first gate structure and the second gate structure are spaced apart from each other in a direction along a top surface of the substrate. The semiconductor device includes a plurality of doped regions in the doped well region, where the plurality of doped regions are spaced apart from each other and arranged in the direction along the top surface of the substrate. The semiconductor device includes a source/drain region in portions of respective doped regions of the plurality of doped regions, where the source/drain region is between the first gate structure and the second gate structure.

The terms “approximately” and “substantially” can indicate a value of a given quantity that varies within 5% of the value (e.g., ±1%, ±2%, ±3%, ±4%, ±5% of the value). These values are merely examples and are not intended to be limiting. It is to be understood that the terms “approximately” and “substantially” can refer to a percentage of the values of a given quantity in light of this disclosure.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor device, comprising:
a substrate comprising a doped well region including a first dopant type; and
an electrostatic discharge (ESD) protection device in the substrate, comprising:
a plurality of discontinuous implant regions in the doped well region, and including a second dopant type,
wherein the plurality of discontinuous implant regions are arranged in a lateral direction in the semiconductor device;
a gate structure above the substrate and adjacent to an edge of an implant region of the plurality of discontinuous implant regions;
a first source/drain region adjacent to a first side of the gate structure; and
a second source/drain region adjacent to a second side of the gate structure opposing the first side,
wherein the second source/drain region includes the second dopant type.

2. The semiconductor device of claim 1, wherein the second source/drain region comprises a continuous implant segment extending in the lateral direction through the plurality of discontinuous implant regions, and
wherein the continuous implant segment includes the second dopant type.

3. The semiconductor device of claim 2, further comprising an oxide layer over the continuous implant segment and over a portion of the gate structure.

4. The semiconductor device of claim 1, wherein the second source/drain region comprises a plurality of discontinuous implant segments,
wherein respective implant segments of the plurality of discontinuous implant segments include the second dopant type, and
wherein the respective implant segments are disposed in respective implant regions of the plurality of discontinuous implant regions.

5. The semiconductor device of claim 4, further comprising:
a first source/drain contact coupled to the first source/drain region; and
a second source/drain contact coupled to an implant segment of the plurality of discontinuous implant segments.

6. The semiconductor device of claim 4, wherein a portion of one or more implant segments of the plurality of discontinuous implant segments is disposed in part of the doped well region.

7. The semiconductor device of claim 4, further comprising an oxide layer over the plurality of discontinuous implant segments and over a portion of the gate structure.

8. The semiconductor device of claim 1, wherein adjacent ones of the plurality of discontinuous implant regions are spaced apart from each other in the lateral direction, and wherein portions of the doped well region are in spaces between the adjacent ones of the plurality of discontinuous implant regions.

9. The semiconductor device of claim 8, wherein a width of a portion of the doped well region in a space between the adjacent ones of the plurality of discontinuous implant regions is included in a range of approximately 0.1 micrometers to approximately 0.5 micrometers.

10. A method, comprising:
forming a plurality of discontinuous implant regions in a doped well region of a substrate of a semiconductor device,
wherein portions of the doped well region are located laterally between adjacent implant regions of the plurality of discontinuous implant regions;
forming, above a portion of the doped well region, a gate structure of an electrostatic discharge (ESD) protection device; and
forming a source/drain region in the plurality of discontinuous implant regions,
wherein the source/drain region is adjacent to a side of the gate structure.

11. The method of claim 10, wherein forming the plurality of discontinuous implant regions comprises:
forming a mask on the portions of the doped well region; and
performing an ion implantation process on other portions of the doped well region left exposed by the mask to form the plurality of discontinuous implant regions in the other portions of the doped well region.

12. The method of claim 10, wherein forming the source/drain region in the plurality of discontinuous implant regions comprises performing an ion implantation process on the plurality of discontinuous implant regions and on the portions of the doped well region between the adjacent implant regions of the plurality of discontinuous implant regions to form a continuous source/drain segment in the plurality of discontinuous implant regions and in the portions of the doped well region.

13. The method of claim 12, further comprising:
depositing one or more dielectric layers on the substrate over the continuous source/drain segment and over the gate structure;
etching the one or more dielectric layers to form a recess exposing a surface of the continuous source/drain segment; and
depositing conductive material in the recess to form a contact on the surface of the continuous source/drain segment.

14. The method of claim 10, wherein forming the source/drain region in the plurality of discontinuous implant regions comprises:
forming a mask on the portions of the doped well region; and
performing an ion implantation process on exposed portions of the plurality of discontinuous implant regions left exposed by the mask to form a plurality of discontinuous source/drain segments in the plurality of discontinuous implant regions.

15. The method of claim 14, further comprising:
depositing one or more dielectric layers on the substrate over the plurality of discontinuous source/drain segments and over the gate structure;
etching the one or more dielectric layers to form a recess exposing a surface of a source/drain segment of the plurality of discontinuous source/drain segments; and
depositing conductive material in the recess to form a contact on the surface of the source/drain segment.

16. A semiconductor device, comprising:
a substrate comprising a doped well region;
a first gate structure and a second gate structure on the substrate,
wherein the first gate structure and the second gate structure are spaced apart from each other in a direction along a top surface of the substrate;
a plurality of doped regions in the doped well region,
wherein the plurality of doped regions are spaced apart from each other and arranged in the direction along the top surface of the substrate; and
a source/drain region in portions of respective doped regions of the plurality of doped regions,
wherein the source/drain region is between the first gate structure and the second gate structure.

17. The semiconductor device of claim 16, wherein a dopant concentration of the source/drain region is greater than a dopant concentration of the plurality of doped regions.

18. The semiconductor device of claim 16, wherein the source/drain region comprises a continuous segment from an edge of the first gate structure to an edge of the second gate structure, and
wherein the continuous segment extends in the direction along the top surface of the substrate through the plurality of doped regions and through portions of the doped well region laterally adjacent to the plurality of doped regions.

19. The semiconductor device of claim 16, wherein the source/drain region comprises a plurality of non-contiguous segments between an edge of the first gate structure and an edge of the second gate structure, and
wherein the plurality of non-contiguous segments are spaced apart from each other and arranged in the direction along the top surface of the substrate.

20. The semiconductor device of claim 19, wherein the plurality of non-contiguous segments are disposed in top portions of the respective doped regions.
